(19) United States
(12) Patent Application Publication
(10) Pub. No.: US 2026/0182193 A1
(43) Pub. Date: Jun. 25, 2026

(54) Display Panel and Display Device Including the Same

(71) Applicant: LG Display Co., Ltd., Seoul (KR)

(72) Inventors: Seunghwan Shin, Jeonju-si (KR); Wonho Lee, Paju-si (KR); Chaiwon Kim, Seongnam-si (KR)

(21) Appl. No.: 19/377,465

(22) Filed: Nov. 3, 2025

(30) Foreign Application Priority Data
Dec. 20, 2024 (KR) 10-2024-0192751

(51) Int. Cl. H10K 59/35; H10K 59/131

(52) U.S. Cl. CPC H10K 59/353; H10K 59/131; H10K 59/351

(57) ABSTRACT

A display panel is disclosed herein in which an arrangement of light-emitting areas and driving circuits of sub-pixels are constructed so that a sensing time required to sense the sub-pixels is reduced. The driving circuit of a sub-pixel of the plurality of sub-pixels of each of a first pixel and a second pixel arranged in a first row is disposed on a first side of opposing sides in a column direction of the light-emitting area of the sub-pixel. Each of respective driving circuits of sub-pixels of the plurality of sub-pixels other than the sub-pixel is disposed on a second side of opposing sides in a column direction of each of respective light-emitting areas of the sub-pixels other than the sub-pixel.

### CROSS-REFERENCE TO RELATED APPLICATION

The present application claims priority to Republic of Korea Patent Application No. 10-2024-0192751, filed Dec. 20, 2024, which is incorporated by reference in its entirety.

### BACKGROUND

### Field

The present disclosure relates to a display device, and more particularly, to a display panel in which an arrangement of sub-pixels in each pixel is adjusted to reduce a time taken for sensing the sub-pixels, and a display device including the same.

### Description of Related Art

Display devices used in a computer monitor, a TV, a mobile phone, or the like include an organic light-emitting display device (OLED) that emits light by itself, and a liquid crystal display device (LCD) that requires a separate light source.

Among these various display devices, the organic light-emitting display device includes a display panel including a plurality of sub-pixels and a driver for driving the display panel. The driver includes a gate driver for supplying a gate signal to the display panel and a data driver for supplying a data voltage. When a signal such as a gate signal and a data voltage is supplied to a sub-pixel of the organic light-emitting display device, the selected sub-pixel may emit light to display an image.

However, there was a problem that one sub-pixel was sensed at one scan such that a sensing time increased.

### SUMMARY

Therefore, a display device that senses sub-pixels emitting light of multiple colors at one scan to shorten the sensing time and compensates for an image quality based on the sensing result is required.

Conventionally, one sub-pixel is sensed at one scan, such that there is a problem in that the time required to sense the sub-pixels for image quality compensation increases. In addition, in the related art, two scans cannot be simultaneously performed due to update sensing according to the use of the same data, and accordingly, there is a problem in that the time required for sensing the sub-pixels increases.

Accordingly, the present disclosure is directed to a display panel capable of sensing the sub-pixels in a multiple manner, thereby shortening a time for sensing the sub-pixels.

A technical purpose to be achieved according to one or more embodiments of the present disclosure is to provide a display panel in which a data line divides to a plurality of sub-data lines and a data voltage is applied to one sub-pixel via each sub-data line.

In addition, a technical purpose to be achieved according to one or more embodiments of the present disclosure is to provide a display panel in which each of the plurality of sub-data lines is constructed such that the data voltage is applied to three or two sub-pixels arranged in a first row via one sub-data line or the data voltage is applied to two or three sub-pixels arranged in a second row adjacent to the first row in a column direction via the one sub-data line.

In addition, a technical purpose to be achieved according to one or more embodiments of the present disclosure is to provide a display panel in which the arrangement of the light-emitting areas and the driving circuits of the sub-pixels are constructed so that at least two of the plurality of sub-pixels can be sensed at one sensing.

In addition, a technical purpose to be achieved according to one or more embodiments of the present disclosure is to provide a display panel in which the arrangement of the light-emitting areas and the driving circuits of the sub-pixels are constructed so that at least two of the plurality of sub-pixels can be sensed at one sensing, such that a sensing time required to sense the sub-pixels in order to compensate for the image quality is reduced.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to one or more embodiments of the present disclosure, the display panel includes a plurality of pixels including first and second pixels arranged in a first row and adjacent to each other, wherein each of the sub-pixels includes a light-emitting area and a driving circuit, wherein in a plan view of the display panel, the driving circuit of one of the plurality of sub-pixels of each of the first and second pixels is disposed on one of both opposing sides in a column direction of the light-emitting area of the one of the plurality of sub-pixels of each of the first and second pixels, wherein each of the respective driving circuits of the others of the plurality of sub-pixels of each of the first and second pixels is disposed on the other of both opposing sides in the column direction of each of the respective light-emitting areas of the others of the plurality of sub-pixels of each of the first and second pixels.

In addition, according to one or more embodiments of the present disclosure, the display panel is configured to drive five pixels arranged in the same row using two data lines.

In addition, according to one or more embodiments of the present disclosure, the plurality of pixels further include a third pixel disposed in the first row and adjacent to the second pixel, wherein the respective driving circuits of all of the plurality of sub-pixels of the third pixel are respectively disposed on the same sides of both opposing sides in the column direction of the respective light-emitting areas of all of the plurality of sub-pixels of the third pixel.

In addition, according to one or more embodiments of the present disclosure, the plurality of pixels further include a fourth pixel disposed in the first row and adjacent to the third pixel, and a fifth pixel disposed in the first row and adjacent to the fourth pixel, wherein the driving circuit of one of the plurality of sub-pixels of each of the fourth and fifth pixels is disposed on one of both opposing sides in a column direction of the light-emitting area of the one of the plurality of sub-pixels of each of the fourth and fifth pixels, wherein each of the respective driving circuits of the others of the plurality of sub-pixels of each of the fifth and fourth pixels is disposed on the other of both opposing sides in the column direction of each of the respective light-emitting areas of the others of the plurality of sub-pixels of each of the fourth and fifth pixels.

According to one or more embodiments of the present disclosure, the sub-pixels which emit light of different colors and do not share the data are sensed and driven based on the sensing result, thereby reducing the sensing time.

In addition, according to one or more embodiments of the present disclosure, the sub-pixels and each of the plurality of sub-data lines is arranged such that the data voltage is applied to three or two sub-pixels arranged in a first row via one sub-data line or the data voltage is applied to two or three sub-pixels arranged in a second row adjacent to the first row in a column direction via the one sub-data line, and the plurality of sub-pixels are sensed at one sensing such that a total sensing time may be shortened.

In addition, according to one or more embodiments of the present disclosure, the arrangement of the light-emitting areas and the driving circuits of the sub-pixels are constructed so that at least two of the plurality of sub-pixels can be sensed at one sensing, such that a sensing time required to sense the sub-pixels in order to compensate for the image quality is reduced. Thus, a plurality of sub-pixels may be sensed at one sensing.

In addition, according to one or more embodiments of the present disclosure, power consumption may be reduced by sensing the plurality of sub-pixels at one sensing.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

FIG. 1 is a schematic diagram of a display device according to one or more embodiments of the present disclosure.

FIG. 2 is a circuit diagram of a sub-pixel of a display device according to one or more embodiments of the present disclosure.

FIG. 3 is a first example diagram illustrating an arrangement relationship of sub-pixels of a display panel according to one or more embodiments of the present disclosure.

FIG. 4 is an example diagram illustrating a sensing sequence of a plurality of sub-pixels in FIG. 3.

FIG. 5 is an example diagram of sensing and recovery in FIG. 4.

FIG. 6 is a second example diagram illustrating an arrangement relationship of sub-pixels of a display panel according to one or more embodiments of the present disclosure.

FIG. 7 is an example diagram illustrating a sensing sequence of a plurality of sub-pixels in FIG. 6.

FIG. 8 is an example diagram of sensing and recovery in FIG. 7.

FIG. 9 is a first example diagram illustrating an arrangement of a light-emitting area and a driving circuit of each sub-pixel of a display panel according to one or more embodiments of the present disclosure.

FIG. 10 is an example diagram illustrating a sensing sequence of a plurality of sub-pixels in FIG. 9 in a table manner.

FIG. 11 is a second example diagram illustrating an arrangement of a light-emitting area and a driving circuit of each sub-pixel of a display panel according to one or more embodiments of the present disclosure.

FIG. 12 is an example diagram illustrating a sensing sequence of a plurality of sub-pixels in FIG. 11 in a table manner.

FIG. 13 is a third example diagram illustrating an arrangement of a light-emitting area and a driving circuit of each sub-pixel of a display panel according to one or more embodiments of the present disclosure.

FIG. 14 is an example diagram illustrating sub-pixels of FIG. 13 which are grouped into groups on a data basis.

FIG. 15 is an example diagram illustrating a sensing state of a sub-pixel disposed in a first row according to a first sensing in the display panel shown in FIG. 13.

FIG. 16 is an example diagram illustrating a sensing state of a sub-pixel according to a second sensing after FIG. 15.

FIG. 17 is an example diagram illustrating a sensing state of a sub-pixel according to a third sensing after FIG. 16.

FIG. 18 is an example diagram illustrating a sensing state of a sub-pixel according to a fourth sensing after FIG. 17.

FIG. 19 is an example diagram illustrating a sensing state of a sub-pixel according to a fifth sensing after FIG. 18.

FIG. 20 is an example diagram illustrating a sensing state of a sub-pixel according to a sixth sensing after FIG. 19.

FIG. 21 is an example diagram illustrating a plurality of sub-pixels that emit light according to the first to sixth sensing in FIGS. 15 to 20 in a table manner.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When one or more certain embodiments may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When one or more embodiments may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the present disclosure.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally. In a plan view of the display device, a column direction and a row direction intersecting each other are used to define an extension direction of a component, for example, a line.

Hereinafter, various embodiments of the present disclosure will be described in detail with reference to the accompanying drawings.

A transistor used in the display device of the present disclosure may be embodied as one or more transistors of an n-channel transistor NMOS and a p-channel transistor PMOS. The transistor may be embodied as an oxide semiconductor transistor having an oxide semiconductor layer as an active layer or a LTPS transistor having a low temperature poly-silicon (LTPS) layer as an active layer. The transistor may include at least a gate electrode, a source electrode, and a drain electrode. The transistor may be embodied as a thin-film transistor (TFT) on the display panel. The carriers in the transistor flow from the source electrode to the drain electrode. In the n-channel transistor NMOS, since the carriers are electrons, the source voltage is lower than the drain voltage so that electrons may flow from the source electrode to the drain electrode. In the n-channel transistor NMOS, the current flows from the drain electrode to the source electrode, and the source electrode may be an output terminal. In the p-channel transistor PMOS, since the carrier is a hole, the source voltage is higher than the drain voltage so that the hole may flow from the source electrode to the drain electrode. In the p-channel transistor PMOS, since holes flow from the source electrode to the drain electrode, a current flows from the source electrode to the drain electrode, and the drain electrode may be an output terminal. Therefore, it should be noted that the source and the drain of the transistor are not fixed because the source and the drain may be exchanged with each other based on the applied voltage. In the present disclosure, it is assumed that the transistor is an n-channel transistor (NMOS). However, embodiments of the present disclosure are not limited thereto, and the transistor may be embodied as a p-channel transistor, and accordingly, a circuit configuration may be changed.

The source may be the drain and the drain may be the source. Also, the source in any one aspect of the present disclosure may be the drain in another aspect of the present disclosure, and the drain in any one aspect of the present disclosure may be the source in another aspect of the present disclosure.

A gate signal of a transistor used as each of switch elements swings between a gate-on voltage and a gate-off voltage. The gate-on voltage is set to a voltage higher than the threshold voltage Vth of the transistor, and the gate-off voltage is set to a voltage lower than the threshold voltage Vth of the transistor. The transistor is turned on in response to the gate-on voltage VGL, while being turned off in response to the gate-off voltage VGL. In the NMOS, the gate-on voltage may be the gate high voltage VGH, and the gate-off voltage may be the gate low voltage VGL. In the PMOS, the gate-on voltage may be the gate low voltage VGL, and the gate-off voltage may be the gate high voltage VGH.

Hereinafter, various embodiments of the present disclosure will be described in detail with reference to the accompanying drawings. The scales of the components shown in the drawings have different scales from the actual ones for convenience of explanation, and thus are not limited to the scales shown in the drawings.

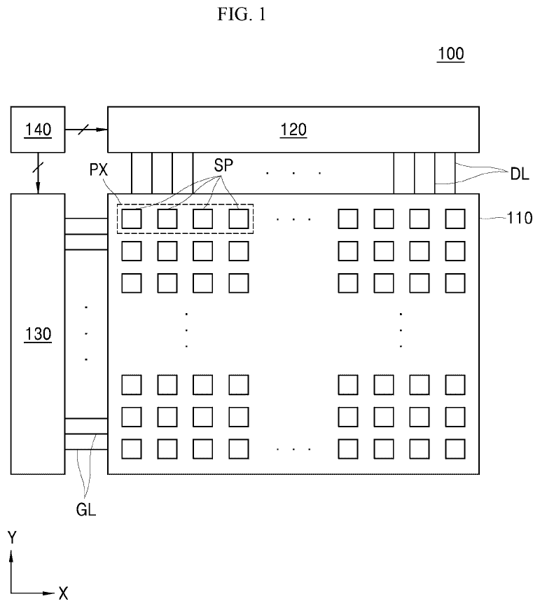

FIG. 1 is a schematic diagram of a display device according to one or more embodiments of the present disclosure.

Referring to FIG. 1, a display device 100 according to one or more embodiments of the present disclosure may include a display panel 110, a data driver 120, a gate driver 130, and a timing controller 140.

The configuration of the display panel 110 illustrated in FIG. 1 is merely according to one or more embodiments, and the components of the display panel 110 are not limited to those in the one or more embodiments as illustrated in FIG. 1, and some components may be added, changed, or deleted as necessary.

The display panel 110 may be a rigid display panel or a flexible display panel capable of shape deformation, such as a foldable, bendable, rollable, and stretchable display panel.

According to one or more embodiments, the display panel 110 is a panel for displaying an image. The display panel 110 may include various circuits, lines, and light-emitting elements disposed on a substrate. An area of the display panel 110 may divide into pixels areas defined by a plurality of data lines DL and a plurality of gate lines GL intersecting each other, and may include a plurality of pixels PX respectively disposed in the pixel areas and connected to the plurality of data lines DL and the plurality of gate lines GL.

The display panel 110 may include a display area including the plurality of pixels PX and a non-display area in which various signal lines or pads are formed, without being limited thereto. Various signal lines may be used for driving the plurality of pixels PX.

The display panel 110 may be embodied as a display panel 110 used in various display devices such as a liquid crystal display device, an organic light-emitting display device, an electrophoretic display device, a micro LED (Micro Light Emitting Diode) display device, a self-emission display device, and the like. In the example where the display device is a self-emission display device, each of the plurality of pixels PX may include a light emitting element.

Hereinafter, an example is described in which the display panel 110 is a panel used in an organic light-emitting display device. However, embodiments of the present disclosure are not limited thereto.

According to one or more embodiments, the timing controller 140 may receive a timing signal such as a vertical synchronization signal, a horizontal synchronization signal, a data enable signal, and a dot clock via a receiving circuit such as an LVDS or TMDS interface connected to a host system. The timing controller 140 may generate timing control signals for controlling the data driver 120 and the gate driver 130 based on the input timing signal.

According to one or more embodiments, the data driver 120 may supply a data voltage DATA to the plurality of sub-pixels SP. The data driver 120 may include a plurality of source drive integrated circuits (IC). The plurality of source drive IC may receive digital video data and a source timing control signal from the timing controller 140.

The plurality of source drive ICs may convert the digital video data into a gamma voltage in response to the source timing control signal to generate the data voltage DATA, and may supply the data voltage DATA via the data line DL of the display panel 110. The plurality of source drive ICs may be connected to the data line DL of the display panel 110 in a chip on glass (COG) process or a tape automated bonding (TAB) process.

In addition, the source drive ICs may be formed on the display panel 110, or may be formed on a separate PCB substrate which may be connected to the display panel 110.

According to one or more embodiments, the gate driver 130 may supply a gate signal to the plurality of sub-pixels SP. The gate driver 130 may include a level shifter and a shift register. The level shifter may shift a level of a clock signal input from the timing controller 140 to a transistor-transistor-logic (TTL) level and then supply the signal having the shifted level to the shift register. The shift register may be formed in the non-display area of the display panel 110 in an GIP (gate in panel) manner. However, embodiments of the present disclosure are not limited thereto.

Alternatively, the gate driver 130 may be disposed in the display area of the display panel 110. The gate driver 130 may be disposed on the substrate, or connected to the substrate. In an example where the gate driver 130 is implemented by the GIP technique, the gate driver 130 may be disposed in the non-display area of the substrate. The gate driver 130 may be connected to the substrate in an example where the gate driver 130 is implemented by the chip-on-glass (COG) technique, the chip-on-film (COF) technique, or the like.

The shift register may include a plurality of stages that shift and output the gate signal in response to the clock signal and a driving signal. The plurality of stages included in the shift register may sequentially output the gate signal via a plurality of output terminals.

According to one or more embodiments, the display panel 110 may include a plurality of sub-pixels SP. The plurality of sub-pixels SP may be sub-pixels SP for emitting light of different colors. For example, the plurality of sub-pixels SP may include a red sub-pixel, a green sub-pixel, a blue sub-pixel, and a white sub-pixel. However, embodiments of the present disclosure are not limited thereto. The plurality of sub-pixels SP may constitute the pixel PX.

That is, the red sub pixel, the green sub pixel, the blue sub pixel, and the white sub pixel may constitute a single pixel PX, and the display panel 110 may include a plurality of pixels PX.

According to one or more embodiments, a first pixel of the display panel 110 may include a plurality of sub-pixels, and a second pixel thereof may include a plurality of sub-pixels. In addition, the second pixel may be disposed at a position adjacent to the first pixel in the first direction (e.g., the x-axis direction).

According to one or more embodiments, a second sub-pixel of the first pixel may be disposed at a position adjacent to a first sub-pixel of the first pixel in the first direction (e.g., the x-axis direction) of. In addition, a third sub-pixel of the first pixel may be disposed at a position adjacent to the second sub-pixel of the first pixel in the first direction (e.g., the x-axis direction). In addition, a fourth sub-pixel of the first pixel may be disposed at a position adjacent to the third sub-pixel of the first pixel in the first direction (e.g., the x-axis direction). However, embodiments of the present disclosure are not limited thereto.

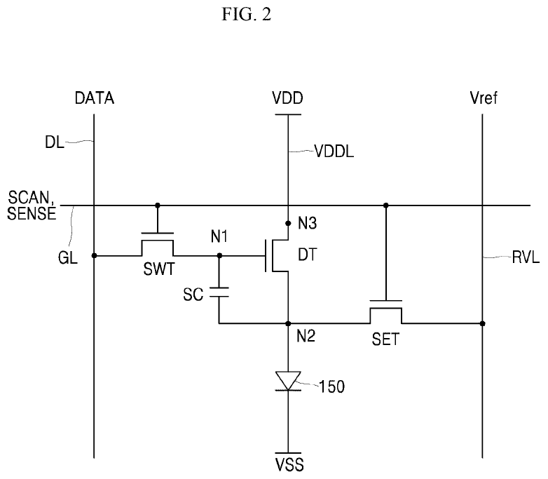

Hereinafter, for a more detailed description of a driving circuit for driving one sub-pixel SP, FIG. 2 will be referred to together with FIG. 1.

FIG. 2 is a circuit diagram of a sub-pixel of a display device according to one or more embodiments of the present disclosure.

FIG. 2 illustrates a circuit diagram of one sub-pixel SP among the plurality of sub-pixels SP of the display device 100.

Referring to FIG. 2, the sub-pixel SP may include a switching transistor SWT, a sensing transistor SET, a driving transistor DT, a storage capacitor SC, and a light-emitting element 150.

According to one or more embodiments, the light-emitting element 150 may include an anode, an organic layer stack, and a cathode. The organic layer stack may include a stack of various organic layers such as a hole injection layer, a hole transport layer, an organic light-emitting layer, an electron transport layer, and an electron injection layer. The anode of the light-emitting element 150 may be connected to an output terminal of the driving transistor DT, and a low potential voltage VSS may be applied to the cathode of the light-emitting element 150.

Although FIG. 2 illustrates that the light-emitting element 150 is embodied as the organic light-emitting element 150, the present disclosure is not limited thereto, and an inorganic light-emitting diode, that is, LED, may also be used as the light-emitting element 150.

Referring to FIG. 2, the switching transistor SWT is a transistor for transferring the data voltage DATA to a first node N1 connected to a gate electrode of the driving transistor DT. The switching transistor SWT is connected to the gate line GL and the data line DL. The switching transistor SWT may include a drain electrode connected to the data line DL, a gate electrode connected to the gate line GL, and a source electrode connected to the gate electrode of the driving transistor DT. The switching transistor SWT may be turned on based on a gate voltage GATE applied from the gate line GL to transmit the data voltage DATA supplied from the data line DL to the first node N1 connected to the gate electrode of the driving transistor DT. Also, the switching transistor SWT may be turned on based on a gate voltage GATE applied from the gate line GL to transmit the data voltage DATA supplied from the data line DL to one electrode of the storage capacitor SC.

Referring to FIG. 2, the driving transistor DT is a transistor for driving the light-emitting element 150 by supplying a driving current to the light-emitting element 150. The driving transistor DT may include a gate electrode connected to the first node N1, a source electrode connected to a second node N2 and corresponding to an output terminal, and a drain electrode connected to a third node N3 and corresponding to an input terminal.

The driving transistor DT is turned on according to the data signal applied to the gate electrode thereof. As a result, the current proportional to the data signal is supplied to the light-emitting element 150 through the driving transistor DT and then the light-emitting element 150 emits light with a luminance proportional to the current flowing through the driving transistor DT.

The gate electrode of the driving transistor DT may be connected to the switching transistor SWT, a drain electrode thereof may receive a high potential voltage VDD via a high potential voltage line VDDL, and a source electrode thereof may be connected to the anode of the light-emitting element 150.

Referring to FIG. 2, the storage capacitor SC is a capacitor for maintaining a voltage corresponding to the data voltage DATA for one frame. One electrode of the storage capacitor SC may be connected to the first node N1, and the other electrode thereof may be connected to the second node N2.

In one example, in the display device 100, as an operation time of each sub-pixel SP increases, degradation of a circuit element such as the driving transistor DT may proceed. Accordingly, an intrinsic characteristic value of the circuit element such as the driving transistor DT may be changed.

In this regard, the intrinsic characteristic value of the circuit element may include the threshold voltage Vth of the driving transistor DT, the mobility α of the driving transistor DT, etc. The change in the intrinsic characteristic value of the circuit element may cause a change in luminance of the corresponding sub-pixel SP.

Therefore, the change in the intrinsic characteristic value of the circuit element may be used as the same concept as the change in the luminance of the sub-pixel SP.

In addition, the change amount in the intrinsic characteristic value of the circuit element of each sub-pixel SP may vary depending on the deterioration amount of each circuit element. Thus, the change amounts in the intrinsic characteristic value of the circuit elements of different sub-pixels SP having the different deterioration amounts of the circuit elements thereof may be different from each other. Such a difference between the change amounts in the intrinsic characteristic value of the respective circuit elements of the sub-pixels may cause a luminance deviation between luminance of the sub-pixels SP.

Therefore, the deviation between the intrinsic characteristic value of the circuit elements of the different sub-pixels SP may be used as the same concept as the luminance deviation between the luminance of the different sub-pixels SP.

The change in the intrinsic characteristic value of the circuit element, that is, the change in the luminance of the sub-pixel SP and the deviations between in the intrinsic characteristic values of the circuit elements of the sub-pixels, that is, the deviation between the luminance of the sub-pixels SP, may cause problems such as a decrease in accuracy of the luminance realized in the sub-pixel SP or a screen abnormality.

Accordingly, in the sub-pixel SP of the display device 100 according to one or more embodiments of the present disclosure, a sensing function of sensing the intrinsic characteristic value of the sub-pixel SP and a compensation function of compensating for the intrinsic characteristic value of the sub-pixel SP based on the sensing result may be provided.

Accordingly, as shown in FIG. 2, the sub-pixel SP may further include a sensing transistor SET for effectively controlling the voltage state of the source electrode of the driving transistor DT in addition to the switching transistor SWT, the driving transistor DT, the storage capacitor SC, and the light-emitting element 150.

Referring to FIG. 2, the sensing transistor SET is connected to and disposed between the source electrode of the driving transistor DT and a reference voltage line RVL that supplies a reference voltage Vref. A gate electrode of the sensing transistor SET is connected to the gate line GL. Accordingly, the sensing transistor SET may be turned on based on the sensing signal SENSE applied via the gate line GL to apply the reference voltage Vref supplied via the reference voltage line RVL to the source electrode of the driving transistor DT. In addition, the sensing transistor SET may be used as one of voltage sensing paths for the source electrode of the driving transistor DT.

Referring to FIG. 2, the switching transistor SWT and the sensing transistor SET of the sub-pixel SP may share one gate line GL. That is, the switching transistor SWT and the sensing transistor SET may be connected to the same gate line GL and may receive the same gate signal therefrom. However, for convenience of description, a voltage applied to the gate electrode of the switching transistor SWT is referred to as the gate voltage GATE, and a voltage applied to the gate electrode of the sensing transistor SET is referred to as a sensing signal SENSE. However, the gate voltage GATE and the sensing signal SENSE applied to one sub-pixel SP are the same signal transmitted via the same gate line GL. For example, the sensing transistor SET and the switching transistor SWT may be turned on or off in response to the same signal transmitted via the same gate line GL. Specifically, when the sensing transistor SET is turned on, the switching transistor SWT is also turned on.

However, the present disclosure is not limited thereto, and only the switching transistor SWT may be connected to the gate line GL, and the sensing transistor SET may be connected to a separate sensing line. Accordingly, the gate voltage GATE may be applied to the switching transistor SWT via the gate line GL, and the sensing signal SENSE may be applied to the sensing transistor SET via the sensing line. For example, the sensing transistor SET and the switching transistor SWT may be turned on or off in response to the different signal.

Accordingly, the reference voltage Vref is applied to the source electrode of the driving transistor DT via the sensing transistor SET. For example, when the sensing transistor SET is turned on, the reference voltage Vref is applied to the source electrode of the driving transistor DT. In addition, a voltage for sensing the threshold voltage Vth of the driving transistor DT or the mobility α of the driving transistor DT is detected via the reference voltage line RVL. In addition, the data driver 120 may compensate for the data voltage DATA based on an amount of change in the detected threshold voltage Vth of the driving transistor DT or the detected mobility α of the driving transistor DT.

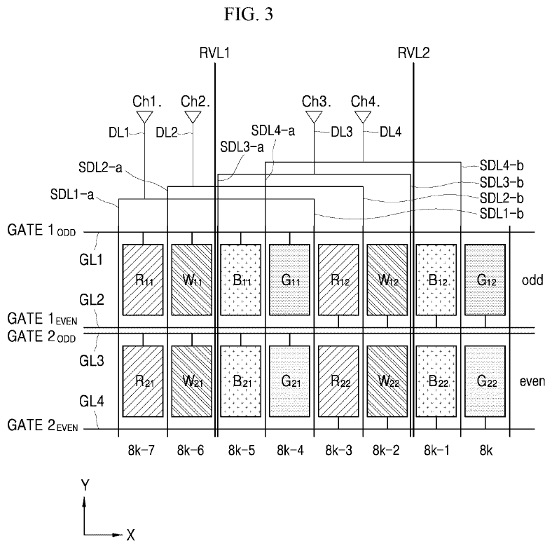

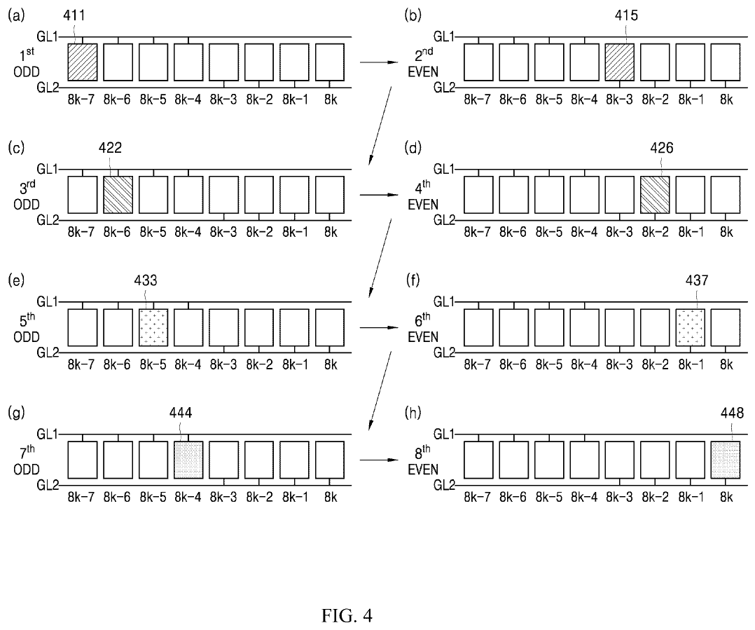

Hereinafter, FIGS. 3 and 4 are referred together to describe an arrangement relationship of a plurality of sub-pixels.

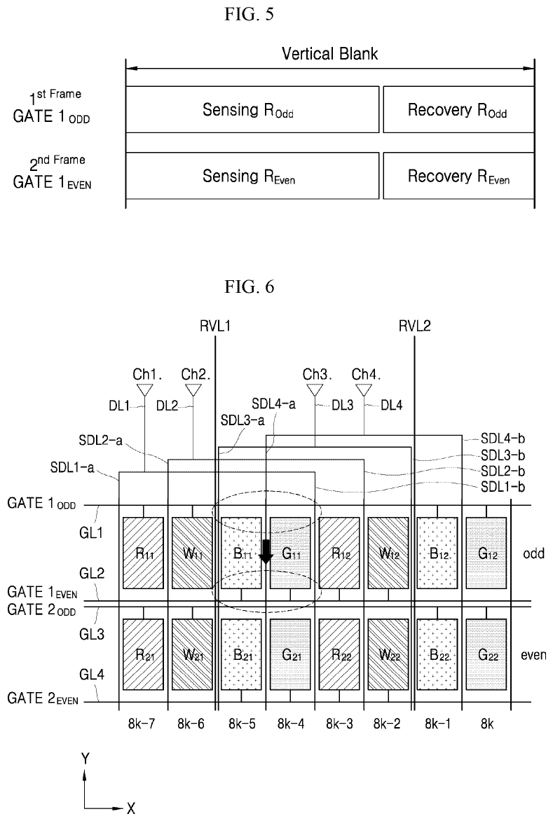

FIG. 3 is a first example diagram illustrating an arrangement relationship of sub-pixels of a display panel according to one or more embodiments of the present disclosure. FIG. 4 is an example diagram illustrating a sensing sequence of a plurality of sub-pixels in FIG. 3. FIG. 5 is an example diagram of sensing and recovery in FIG. 4.

In FIG. 3, for convenience of illustration, only four pixels PX arranged in a 2×2 matrix form are illustrated in FIGS. 3 and 4. An arrangement relationship of four pixels PX arranged in a 2×2 matrix form may be repeated in the display area DA. In addition, a transistor disposed between the sub-pixels R, W, B, and G and the data line means the switching transistor SWT described in FIG. 2.

According to one or more embodiments, each of the plurality of data lines DL1, DL2, DL3, and DL4 may divide into a plurality of sub-data lines SDL1-a and SDL1-b, SDL2-a and SDL2-b, SDL3-a and SDL3-b, or SDL4-a and SDL4-b. Further, the plurality of data lines DL1, DL2, DL3, and DL4 are respectively connected to a plurality of channel terminals Ch1, Ch2, Ch3, and Ch4.

Specifically, the first data line DL1 may divide into a plurality of first sub-data lines SDL1-a and SDL1-b, and the second data line DL2 may divide into a plurality of second sub-data lines SDL2-a and SDL2-b.

The third data line DL3 may divide into the plurality of third sub-data lines SDL3-a and SDL3-b, and the fourth data line DL4 may divide into the plurality of fourth sub-data lines SDL4-a and SDL4-b. However, the present disclosure is not limited thereto.

According to one or more embodiments, the first sub-data lines SDL1-a and SDL1-b may include a (1-a)th sub-data line SDL1-a and a (1-b)th sub-data line SDL1-b, and the second sub-data lines SDL2-a and SDL2-b may include a (2-a)th sub-data line SDL2-a and a (2-b)th sub-data line SDL2-b.

The third sub-data lines SDL3-a and SDL3-b may include a (3-a)th sub-data line SDL3-a and a (3-b)th sub-data line SDL3-b, and the fourth sub-data lines SDL4-a and SDL4-b may include a (4-a)th sub-data line SDL4-a and a (4-b)th sub-data line SDL4-b.

Each of the plurality of high potential voltage lines may be disposed between adjacent ones of the plurality of pixels PX.

According to an embodiment, one pixel PX may include a plurality of sub-pixels SP. According to one or more embodiments, one pixel PX may include four sub-pixels R, W, B, and G. However, the present disclosure is not limited thereto. For example, the one pixel PX may include more or less sub-pixels. For example, as shown in FIG. 3, the pixel PX may include a first sub-pixel R, a second sub-pixel W, a third sub-pixel B, and a fourth sub-pixel G. For example, the first sub-pixel R may be a red sub-pixel, the second sub-pixel W may be a white sub-pixel, the third sub-pixel B may be a blue sub-pixel, and the fourth sub-pixel G may be a green sub-pixel. However, the present disclosure is not limited thereto, and the plurality of sub-pixels may include sub-pixels emitting light of various colors magenta, yellow, and cyan.

In addition, the plurality of sub-pixels emitting light of the same color may be arranged in the same column. That is, the plurality of first sub-pixels R may be arranged in the same column, the plurality of second sub-pixels W may be arranged in the same column, the plurality of third sub-pixels B may be arranged in the same column, and the plurality of fourth sub-pixels G may be arranged in the same column.

More specifically, as illustrated in FIG. 3, the plurality of first sub-pixels R may be arranged in a (8k-7)th column and a (8k-3)th column, and the plurality of second sub-pixels W may be arranged in a (8k-6)th column and a (8k-2)th column. In addition, the plurality of third sub-pixels B may be arranged in a (8k-5)th column and a (8k-1)th column, and the plurality of fourth sub-pixels G may be arranged in a (8k-4)th column and a 8k-th column. However, k means a natural number greater than or equal to 1.

That is, the first sub-pixel R, the second sub-pixel W, the third sub-pixel B, and the fourth sub-pixel G may be sequentially and repeatedly arranged along one odd row or one even row. However, embodiments of the present disclosure are not limited thereto.

According to one embodiment, a plurality sub-pixels of the first pixel may be disposed to adjacent to each other. According to one or more embodiments, a second sub-pixel W of the first pixel may be disposed at a position adjacent to a first sub-pixel R of the first pixel in the first direction (e.g., x-axis direction). In addition, a third sub-pixel B of the first pixel may be disposed at a position adjacent to the second sub-pixel W of the first pixel in the first direction (e.g., x-axis direction). In addition, a fourth sub-pixel G of the first pixel may be disposed at a position adjacent to the third sub-pixel B of the first pixel in the first direction (e.g., x-axis direction). However, embodiments of the present disclosure are not limited thereto. Similarly, a plurality sub-pixels of each of the second to fourth pixels may be disposed to adjacent to each other.

According to one or more embodiments, each of the plurality of first sub-data lines SDL1-a and SDL1-b may be disposed adjacent to the plurality of first sub-pixels R and be respectively connected to the plurality of first sub-pixels R.

Specifically, the (1-a)th sub-data line SDL1-a may be disposed between the plurality of fourth sub-pixels G arranged in a (8k-8)th column (not shown) and the plurality of first sub-pixels R arranged in a (8k-7)th column, and may be electrically connected to the plurality of first sub-pixels R arranged in the (8k-7)th column. In addition, the (1-b)th sub-data line SDL1-b may be disposed between the plurality of fourth sub-pixels G arranged in a (8k-4)th column and the plurality of first sub-pixels R arranged in a (8k-3)th column, and may be electrically connected to the plurality of first sub-pixels R arranged in the (8k-3)th column.

According to one or more embodiments, each of the plurality of second sub-data lines SDL2-a and SDL2-b may be disposed adjacent to the plurality of second sub-pixels W and may be connected to the plurality of second sub-pixels W.

Specifically, the (2-a)th sub-data line SDL2-a may be disposed between the plurality of first sub-pixels R arranged in a (8k-7)th column and the plurality of second sub-pixels W arranged in a (8k-6)th column, and may be electrically connected to the plurality of second sub-pixels W arranged in the (8k-6)th column. In addition, the (2-b)th sub-data line SDL2-b may be disposed between the plurality of first sub-pixels R arranged in a (8k-3)th column and the plurality of second sub-pixels W arranged in a (8k-2)th column and be electrically connected to the plurality of second sub-pixels W arranged in the (8k-2)th column.

According to one or more embodiments, each of the plurality of third sub-data lines SDL3-a and SDL3-b may be disposed adjacent to the plurality of third sub-pixels B and may be connected to the plurality of third sub-pixels B.

Specifically, the (3-a)th sub-data line SDL3-a may be disposed between plurality of second sub-pixels W arranged in the (8k-6)th column and the plurality of third sub-pixels B arranged in a (8k-5)th column, and may be electrically connected to the plurality of third sub-pixels B arranged in the (8k-5)th column. In addition, the (3-b)th sub-data line SDL3-b may be disposed between the plurality of second sub-pixels W arranged in a (8k-2)th column and the plurality of third sub-pixels B arranged in a (8k-1)th column, and may be electrically connected to the plurality of third sub-pixels B arranged in the (8k-1)th column.

According to one or more embodiments, each of the plurality of fourth sub-data lines SDL4-a and SDL4-W may be disposed adjacent to the plurality of fourth sub-pixels G and may be connected to the plurality of fourth sub-pixels G.

Specifically, the (4-a)th sub-data line SDL4-a may be disposed between the plurality of third sub-pixels B arranged in a (8k-5)th column and the plurality of fourth sub-pixels G arranged in a (8k-4)th column, and may be electrically connected to the plurality of fourth sub-pixels G arranged in the (8k-4)th column. The (4-b)th sub-data lines SDL4-b may be disposed between the plurality of third sub-pixels B arranged in a (8k-1)th column and the plurality of fourth sub-pixels G arranged in a 8k-th column, and may be electrically connected to the plurality of fourth sub-pixels G arranged in the 8k-th column.

According to one or more embodiments, a first data voltage DATA1 as a red data voltage may be applied to the first data line DL1, and a second data voltage DATA2 as a white data voltage may be applied to the second data line DL2. In addition, a third data voltage DATA3 as a blue data voltage may be applied to the third data line DL3, and a fourth data voltage DATA4 as a green data voltage may be applied to the fourth data line DL4.

Accordingly, the first data voltage DATA1 as a red data voltage may also be applied to the plurality of first sub-data lines SDL1-a and SDL1-b, and the second data voltage DATA2 as a white data voltage may also be applied to the plurality of second sub-data lines SDL2-a and SDL2-b. In addition, the third data voltage DATA3 as a blue data voltage may also be applied to the plurality of third sub-data lines SDL3-a and SDL3-b, and the fourth data voltage DATA4 as a green data voltage may also be applied to the plurality of fourth sub-data lines SDL4-a and SDL4-b. However, embodiments of the present disclosure are not limited thereto.

According to one or more embodiments, each of the plurality of gate lines GL1 to GL4 may be disposed on each of both opposing sides in the column direction of a row of the plurality of sub-pixels R, W, B and G. Two gate lines GL2 and GL3 may be disposed between adjacent rows of the plurality of sub-pixels R, W, B and G.

Specifically, referring to FIG. 3, the first gate line GL1 and the second gate line GL2 may be respectively disposed on both opposing sides in the column direction of the plurality of sub-pixels R, W, B and G of the odd-numbered row, while the third gate line GL3 and the fourth gate line GL4 may be respectively disposed on both opposing sides in the column direction of the plurality of sub-pixels R, W, B and G of the even-numbered row. Accordingly, the second gate line GL2 and the third gate line GL3 may be disposed between the plurality of sub-pixels R, W, B and G arranged in the odd-numbered row and the plurality of sub-pixels R, W, B and G arranged in the even-numbered row even.

Each of the plurality of pixels PX may be connected to the same gate line GL1 to GL4, and adjacent pixels PX among the plurality of pixels PX may be connected to different gate lines GL1 to GL4. For example, the sub-pixels R₁₂, W₁₂, B₁₂, and G₁₂ of each of the plurality of pixels PX may be connected to the same gate line GL1 to GL4, and the sub-pixels R₁₂, W₁₂, B₁₂, and G₁₂ of adjacent pixels PX among the plurality of pixels PX may be connected to different gate lines GL1 to GL4.

Specifically, referring to FIG. 3, the sub-pixels R₁₁, W₁₁, B₁₁, and G₁₁ arranged in a (8k-7)th column to the (8k-4)th column of the odd-numbered row odd may be connected to the first gate line GL1, and the sub-pixels R₁₂, W₁₂, B₁₂, and G₁₂ arranged in a (8k-3)th column to the 8k-th column of the odd-numbered row odd may be connected to the second gate line GL2. In addition, the sub-pixels R₂₁, W₂₁, B₂₁, and G₂₁ arranged in a (8k-7)th column to the (8k-4)th column of the even-numbered row even may be connected to the third gate line GL3, while the sub-pixels R₂₂, W₂₂, B₂₂, and G₂₂ arranged in a (8k-3)th column to the 8k-th column of the even-numbered row even may be connected to the fourth gate line GL4. However, embodiments of the present disclosure are not limited thereto.

Each of the plurality of reference voltage lines RVL may be disposed inside one pixel PX, and each of the plurality of high potential voltage lines may be disposed between adjacent ones of the plurality of pixels PX.

Specifically, a first reference voltage line RVL1 may be disposed between the plurality of second sub-pixels W arranged in a (8k-6)th column and the plurality of third sub-pixels B arranged in a (8k-5)th column. A second reference voltage line RVL2 may be disposed between the plurality of second sub-pixels W arranged in a (8k-2)th column and the plurality of third sub-pixels B arranged in a (8k-1)th column. However, embodiments of the present disclosure are not limited thereto.

Referring to (a) in FIG. 4, when a gate voltage GATE1 at a turn-on level is applied via the first gate line GL1 in a state in which the data voltage is being supplied (1^{st} odd), the gate signal is transmitted to the first sub-pixel R 411 disposed in the (8k-7)th column via the first gate line GL1, and the data voltage is charged to the first sub-pixel R 411 disposed in the (8k-7)th column, and thus the first sub-pixel R 411 disposed in the (8k-7)th column is sensed.

Thereafter, as shown in (b) in FIG. 4, when the gate voltage GATE1 at a turn-on level is applied via the second gate line GL2 (2^{nd} even), the gate signal is transmitted to the first sub-pixel R 4₁₅ disposed in the (8k-3)th column via the second gate line GL2, and the data voltage is charged in the first sub-pixel R 4₁₅ disposed in the (8k-3)th column, such that the first sub-pixel R 4₁₅ disposed in the (8k-3)th column is sensed.

Thereafter, as shown in (c) in FIG. 4, when the gate voltage GATE1 at a turn-on level is applied via the first gate line GL1 (3^{rd} odd), the gate signal is transmitted to the second sub-pixel W 422 disposed in the (8k-6)th column via the first gate line GL1, and the data voltage is charged in the second sub-pixel W 422 disposed in the (8k-6)th column to sense the second sub-pixel W 422 disposed in the (8k-6)th column.

Thereafter, as shown in (d) in FIG. 4, when the gate voltage GATE1 at a turn-on level is applied via the second gate line GL2 (4^{th} even), the gate signal is transmitted to the second sub-pixel W 426 disposed in the (8k-2)th column via the second gate line GL2, and the data voltage is charged in the second sub-pixel W 426 disposed in the (8k-2)th column, such that the second sub-pixel W 426 disposed in the (8k-2)th column is sensed.

Thereafter, as shown in (e) in FIG. 4, when the gate voltage GATE1 at a turn-on level is applied via the first gate line GL1 (5^{th} odd), the gate signal is transmitted to the third sub-pixels B and 433 disposed in the (8k-5)th column via the first gate line GL1, and the data voltage is charged in the third sub-pixels B 433 disposed in the (8k-5)th column, such that the third sub-pixels B and 433 disposed in the (8k-5)th column are sensed.

Thereafter, as shown in (f) in FIG. 4, when the gate voltage GATE1 at a turn-on level is applied via the second gate line GL2 (6^{th} even), the gate signal is transmitted to the third sub-pixels B 437 disposed in the (8k-1)th column via the second gate line GL2, and the data voltage is charged in the third sub-pixels B and 437 disposed in the (8k-1)th column, such that the third sub-pixels B and 437 disposed in the (8k-1)th column are sensed.

Thereafter, as shown in (g) of FIG. 4, when the gate voltage GATE1 at a turn-on level is applied via the first gate line GL1 (7^{th} odd), the gate signal is transmitted to the fourth sub-pixel G 444 disposed in the (8k-4)th column via the first gate line GL1, and the data voltage is charged in the fourth sub-pixel G 444 disposed in the (8k-4)th column to sense the fourth sub-pixel G 444 disposed in the (8k-4)th column.

Thereafter, as shown in (h) in FIG. 4, when the gate voltage GATE1 at a turn-on level is applied via the second gate line GL2 (8^{th} even), the gate signal is transmitted to the fourth sub-pixel G 448 disposed in the 8k-th column via the second gate line GL2, the data voltage is charged in the fourth sub-pixel G 448 disposed in the 8k-th column, and the fourth sub-pixel G 448 disposed in the 8k-th column is sensed.

As described above, in order to compensate for the pixels R, W, B, and G of the two pixels PX, two reference voltage lines RVL1 and RVL2 are used, and only one sub-pixel is sensed at one scan, and thus, a total of eight times of scans are performed. In addition, two scans cannot be simultaneously performed due to update sensing according to the use of the same data, and accordingly, the sensing time is doubled.

Referring to FIG. 5, after sensing each sub-pixel, recovery of each sensed sub-pixel is performed. In this recovery, two scans (e.g., odd and even) are performed on a single color. Thus, the recovery time is doubled.

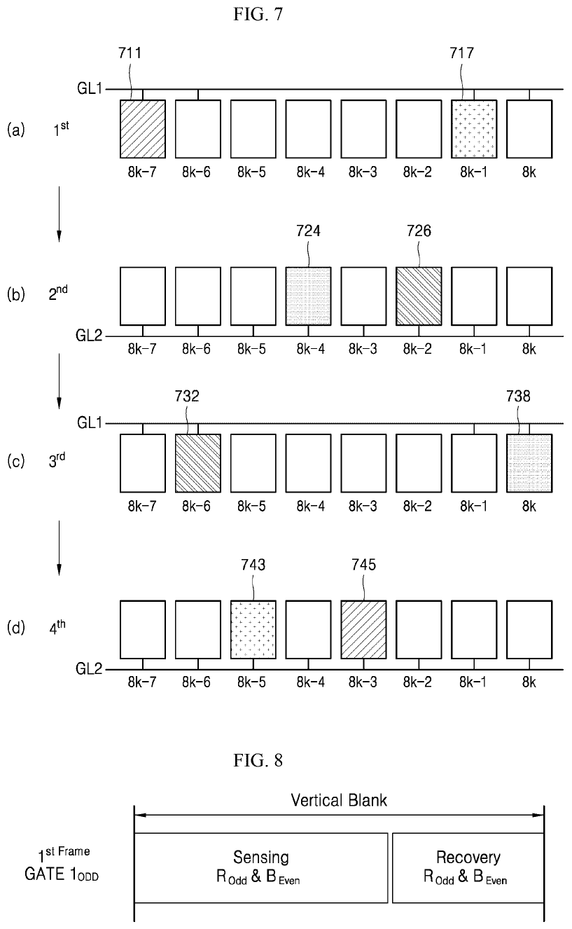

FIG. 6 is a second example diagram illustrating an arrangement relationship of sub-pixels of a display panel according to one or more embodiments of the present disclosure. FIG. 7 is an example diagram illustrating a sensing sequence of a plurality of sub-pixels in FIG. 6. FIG. 8 is an example diagram of sensing and recovery in FIG. 7.

The arrangement of the pixels in FIG. 6 is similar to the arrangement of the pixels in FIG. 3. Therefore, for convenience of description, the same contents as those as described above with reference to FIG. 3 will be omitted.

In FIG. 3, it is illustrated that the sub-pixels R₁₁, W₁₁, B₁₁, and G₁₁ respectively disposed in the (8k-7)th column to the (8k-4)th column of the odd-numbered row odd are connected to the first gate line GL1, and the sub-pixels R₁₂, W₁₂, B₁₂, and G₁₂ respectively disposed in the (8k-3)th column to the 8k-th column of the odd-numbered row odd are connected to the second gate line GL2.

However, in FIG. 6, the sub-pixels R₁₁ and W₁₁ respectively disposed in the (8k-7)th column and the (8k-6)th column of the odd-numbered row odd and the sub-pixels B₁₂ and G₁₂ disposed in the (8k-1)th column and the 8k-th column of the odd-numbered row odd may be connected to the first gate line GL1, and the sub-pixels B₁₁, G₁₁, R₁₂, and W₁₂ respectively disposed in the (8k-5)th column to the (8k-2)th column of the odd-numbered row odd may be connected to the second gate line GL2.

In addition, in FIG. 3, it is illustrated that the sub-pixels R₂₁, W₂₁, B₂₁, and G₂₁ respectively disposed in the (8k-7)th column to the (8k-4)th column of the odd-numbered row odd may be connected to the third gate line GL3, and the sub-pixels R₂₂, W₂₂, B₂₂, and G₂₂ respectively disposed in the (8k-3)th column to the 8k-th column of the odd-numbered row odd may be connected to the fourth gate line GL4.

In addition, in FIG. 6, the sub-pixels R₂₁ and W₂₁ respectively disposed in the (8k-7)th column and the (8k-6)th column of the even-numbered row even and the sub-pixels B₂₂ and G₂₂ disposed in the (8k-1)th column and the 8k-th column of the even-numbered row even may be connected to the third gate line GL3, and the sub-pixels B₂₁, G₂₁, R₂₂, W₂₂ respectively disposed in the (8k-5)th column to the (8k-2)th column of the even-numbered row even may be connected to the fourth gate line GL4.

Referring to (a) in FIG. 7, when the gate voltage GATE1 at a turn-on level is applied via the first gate line GL1 in a state in which the data voltage is being supplied (1^{st} odd), the gate signal is transmitted to the first sub-pixel R 711 disposed in the (8k-7)th column and the third sub-pixel B 717 disposed in the (8k-1)th column via the first gate line GL1, and the data voltage is charged in the first sub-pixel R 711 disposed in the (8k-7)th column and the third sub-pixel B 717 disposed in the (8k-1)th column, such that the first sub-pixel R 711 disposed in the (8k-7)th column and the third sub-pixel B 717 disposed in the (8k-1)th column are sensed.

Thereafter, as shown in (b) in FIG. 7, when the gate voltage GATE1 at a turn-on level is applied via the second gate line GL2 (2^{nd} even), the gate signal is transmitted to the fourth sub-pixel G 7₂₄ disposed in the (8k-4)th column and the second sub-pixel W 726 disposed in the (8k-2)th column via the second gate line GL2, and the data voltage is charged to the fourth sub-pixel G 7₂₄ disposed in the (8k-4)th column and the second sub-pixel W 726 disposed in the (8k-2)th column, such that the fourth sub-pixel G 7₂₄ disposed in the (8k-4)th column and the second sub-pixel W 726 disposed in the (8k-2)th column are sensed.

Thereafter, as shown in (c) in FIG. 7, when the gate voltage GATE1 at a turn-on level is applied via the first gate line GL1 (3^{rd} odd), the gate signal is transmitted to the second sub-pixel W 732 disposed in the (8k-6)th column and the fourth sub-pixel G 738 disposed in the 8k-th column via the first gate line GL1, and the data voltage is charged in the second sub-pixel W 732 disposed in the (8k-6)th column and the fourth sub-pixel G 738 disposed in the 8k-th column, such that the second sub-pixel W 732 disposed in the (8k-6)th column and the fourth sub-pixel G 738 disposed in the 8k-th column are sensed.

Thereafter, as shown in (d) in FIG. 7, when the gate voltage GATE1 at a turn-on level is applied via the second gate line GL2 (4^{th} even), the gate signal is transmitted to the third sub-pixel B 743 disposed in the (8k-5)th column and the first sub-pixel R 745 disposed in the (8k-3)th column via the second gate line GL2, and the data voltage is charged to the third sub-pixel B 743 disposed in the (8k-5)th column and the first sub-pixel R 745 disposed in the (8k-3)th column, such that the third sub-pixel B 743 disposed in the (8k-5)th column and the first sub-pixel R 745 disposed in the (8k-3)th column are sensed.

As described above, the two reference voltage lines RVL1 and RVL2 are used to compensate for the pixels R, W, B, and G of each of the two pixels PX, and two sub-pixels are sensed at one scan, such that a total of four times of scans are performed. For example, compared with the embodiment of FIG. 4, the sensing time is shortened and the times of scans are reduced.

Referring to FIG. 8, after two sub-pixels are sensed, recovery of the sensed two sub-pixels is performed together. In this recovery, one scan (e.g., odd and even) is performed on different colors. Thus, the recovery time is shortened.

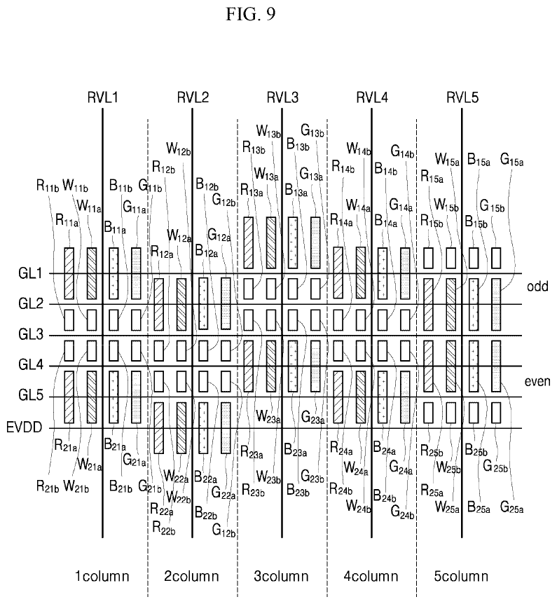

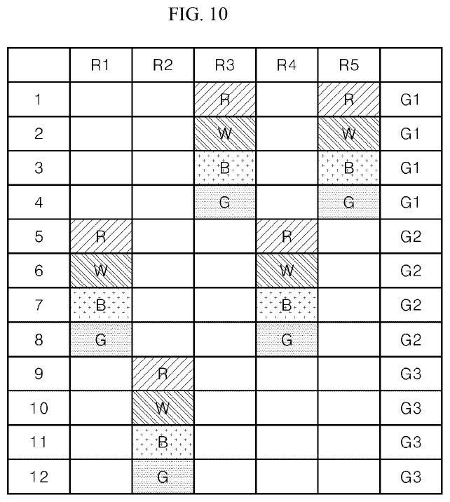

FIG. 9 is a first example diagram illustrating an arrangement of a light-emitting area and a driving circuit of each sub-pixel of a display panel according to one or more embodiments of the present disclosure. FIG. 10 is an example diagram illustrating a sensing sequence of a plurality of sub-pixels in FIG. 9 in a table manner.

Referring to FIGS. 9 and 10, each sub-pixel of the display panel 110 may include a light-emitting area and a driving circuit for controlling light emission of the light-emitting area. Such a driving circuit may be disposed in one or the other of both opposing sides in the column direction of the corresponding light-emitting area. For example, each of the driving circuits R_{11b}, W_{11b}, B_{11b}, and G_{11b} of the first to fourth sub-pixels R₁₁, W₁₁, B₁₁, and G₁₁ of the pixel disposed in the first column of the first row odd is disposed on the other of both opposing sides in the column direction of each of the light-emitting areas R₁₁ₐ, W₁₁ₐ, B₁₁ₐ, and G₁₁ₐ. In addition, the driving circuit of each sub-pixel disposed in each pixel PX may be disposed on one or the other of both opposing sides in the column direction of the corresponding light-emitting area. Thus, the display panel 110 according to the present disclosure is not limited thereto.

As one example, each of a first reference voltage line RVL1 to a fifth reference voltage line RVL 5 is disposed inside each of a pixel of a first column to a pixel of a fifth column, but is not limited thereto. For example, each reference voltage line may be disposed between the sub-pixels of each pixel, but is not limited thereto.

According to one or more embodiments, a plurality of reference voltage lines are disposed in the display panel 110. For example, a first reference voltage line RVL1 is disposed inside a pixel of a first column (e.g., between a second sub-pixel and a third sub-pixel of each pixel), a second reference voltage line RVL2 is disposed inside a pixel of a second column (e.g., between a second sub-pixel and a third sub-pixel of each pixel), a third reference voltage line RVL3 is disposed inside a pixel of a third column (e.g., between a second sub-pixel and a third sub-pixel of each pixel), a fourth reference voltage line RVL 4 is disposed inside a pixel of a fourth column (e.g., between a second sub-pixel and a third sub-pixel of each pixel), and a fifth reference voltage line RVL 5 is disposed inside a pixel of a fifth column (e.g., between a second sub-pixel and a third sub-pixel of each pixel). However, embodiments of the present disclosure are not limited thereto.

As one example, the first gate line GL1 may be disposed between the driving circuits and the light-emitting areas of the first to fourth sub-pixels of the pixel disposed in the third and fifth columns of the first row. However, embodiments of the present disclosure are not limited thereto.

According to one or more embodiments, the first gate line GL1 is disposed between the driving circuits R_{13b}, W_{13b}, B_{13b}, and G_{13b} and the light-emitting areas R₁₃ₐ, W₁₃ₐ, B₁₃ₐ, and G₁₃ₐ of the first to fourth sub-pixels R₁₃, W₁₃, B₁₃, and G₁₃ of the pixel disposed in the third column of the first row. In addition, the first gate line GL1 is disposed between the driving circuit R_{15b}, W_{15b}, B_{15b}, and G_{15b} and the light-emitting areas R₁₅ₐ, W₁₅ₐ, B₁₅ₐ, and G₁₅ₐ of the first to fourth sub-pixels R₁₅, W₁₅, B₁₅, and G₁₅ of the pixel disposed in the fifth column of the first row.

The driving circuits R_{13b}, W_{13b}, B_{13b}, and G_{13b} of the first to fourth sub-pixels R₁₃, W₁₃, B₁₃, and G₁₃ of the pixel disposed in the third column of the first row are respectively disposed on the other of both opposing sides in the column direction of the light-emitting areas R₁₃ₐ, W₁₃ₐ, B₁₃ₐ, and G₁₃ₐ. In addition, the driving circuits R_{15b}, W_{15b}, B_{15b}, and G_{15b} of the first to fourth sub-pixels R₁₅, W₁₅, B₁₅, and G₁₅ of the pixel disposed in the fifth column of the first row are respectively disposed on the other of both opposing sides in the column direction of the light-emitting areas R₁₅ₐ, W₁₅ₐ, B₁₅ₐ, and G₁₅ₐ.

As one example, when the gate signal is applied via the first gate line GL1 in a state in which the data voltage is being supplied, one sub-pixel of the pixel disposed in the third column of the first row and corresponding sub-pixel of the pixel disposed in the fifth column of the first row may be sequentially sensed, but is not limited thereto.

For example, when the gate signal is applied via the first gate line GL1 in a state in which the data voltage is being supplied, the first sub-pixel R₁₃ of the pixel disposed in the third column of the first row and the first sub-pixel R₁₅ of the pixel disposed in the fifth column of the first row are sensed.

Thereafter, when the gate signal is applied via the first gate line GL1 in a state in which the data voltage is being supplied, the second sub-pixel W₁₃ of the pixel disposed in the third column of the first row and the second sub-pixel W₁₅ of the pixel disposed in the fifth column of the first row are sensed.

Thereafter, when the gate signal is applied via the first gate line GL1 in a state in which the data voltage is being supplied, the third sub-pixel B₁₃ of the pixel disposed in the third column of the first row and the third sub-pixel B₁₅ of the pixel disposed in the fifth column of the first row are sensed.

Thereafter, when the gate signal is applied via the first gate line GL1 in a state in which the data voltage is being supplied, the fourth sub-pixel G₁₃ of the pixel disposed in the third column of the first row and the fourth sub-pixel G₁₅ of the pixel disposed in the fifth column of the first row are sensed.

As one example, the second gate line GL2 may be disposed between the driving circuits and the light-emitting areas of the first to fourth sub-pixels of the pixel disposed in the first and fourth columns of the first row. However, embodiments of the present disclosure are not limited thereto.

According to one or more embodiments, the second gate line GL2 is disposed between the driving circuit R_{11b}, W_{11b}, B_{11b}, and G_{11b} and the light-emitting areas R₁₁ₐ, W₁₁ₐ, B₁₁ₐ, and G₁₁ₐ of the first to fourth sub-pixels R₁₁, W₁₁, B₁₁, and G₁₁ of the pixel disposed in the first column of the first row. In addition, the second gate line GL2 is disposed between the driving circuit R_{14b}, W_{14b}, B_{14b}, and G_{14b} and the light-emitting areas R₁₄ₐ, W₁₄ₐ, B₁₄ₐ, and G₁₄ₐ of the first to fourth sub-pixels R₁₄, W₁₄, B₁₄, and G₁₄ of the pixel disposed in the fourth column of the first row.

The driving circuits R_{11b}, W_{11b}, B_{11b}, and G_{11b} of the first to fourth sub-pixels R₁₁, W₁₁, B₁₁, and G₁₁ of the pixel disposed in the first column of the first row are disposed on the other of both opposing sides in the column direction of the light-emitting areas R₁₁ₐ, W₁₁ₐ, B₁₁ₐ, and G₁₁ₐ, respectively. In addition, the driving circuits R_{14b}, W_{14b}, B_{14b}, and G_{14b} of the first to fourth sub-pixels R₁₄, W₁₄, B₁₄, and G₁₄ of the pixel disposed in the fourth column of the first row are respectively disposed on the other of both opposing sides in the column direction of the light-emitting areas R₁₄ₐ, W₁₄ₐ, B₁₄ₐ, and G₁₄ₐ.

As one example, when the gate signal is applied via the second gate line GL2 in a state in which the data voltage is being supplied, one sub-pixel of the pixel disposed in the first column of the first row and corresponding sub-pixel of the pixel disposed in the fourth column of the first row may be sequentially sensed, but is not limited thereto.

For example, when the gate signal is applied via the second gate line GL2 in a state in which the data voltage is being supplied, the first sub-pixel R₁₁ of the pixel disposed in the first column of the first row and the first sub-pixel R₁₄ of the pixel disposed in the fourth column of the first row are sensed.

Thereafter, when the gate signal is applied via the second gate line GL2 in a state in which the data voltage is being supplied, the second sub-pixel W₁₁ of the pixel disposed in the first column of the first row and the second sub-pixel W₁₄ of the pixel disposed in the fourth column of the first row are sensed.

Thereafter, when the gate signal is applied via the second gate line GL2 in a state in which the data voltage is being supplied, the third sub-pixel B₁₁ of the pixel disposed in the first column of the first row and the third sub-pixel B₁₄ of the pixel disposed in the fourth column of the first row are sensed.

Thereafter, when the gate signal is applied via the second gate line GL2 in a state in which the data voltage is being supplied, the fourth sub-pixel G₁₁ of the pixel disposed in the first column of the first row and the fourth sub-pixel G₁₄ of the pixel disposed in the fourth column of the first row are sensed.

As one example, the third gate line GL3 may be disposed between the driving circuits and the light-emitting areas of the first to fourth sub-pixels of the pixel disposed in the second column of the first row and the third column of the second row even. However, embodiments of the present disclosure are not limited thereto.

According to one or more embodiments, the third gate line GL3 is disposed between the driving circuit R_{12b}, W_{12b}, B_{12b}, and G_{12b} and the light-emitting areas R₁₂ₐ, W₁₂ₐ, B₁₂ₐ, and G₁₁ₐ of the first to fourth sub-pixels R₁₂, W₁₂, B₁₂, and G₁₂ of the pixel disposed in the second column of the first row. In addition, the third gate line GL3 is disposed between the driving circuits R_{23b}, W_{23b}, B_{23b}, and G_{23b} and the light-emitting areas R₂₃ₐ, W₂₃ₐ, B₂₃ₐ, and G₂₃ₐ of the first to fourth sub-pixels R₂₃, W₂₃, B₂₃, and G₂₃ of the pixel disposed in the third column of the second row even.

The driving circuits R_{12b}, W_{12b}, B_{12b}, and G_{12b} of the first to fourth sub-pixels R₁₂, W₁₂, B₁₂, and G₁₂ of the pixel disposed in the second column of the first row are respectively disposed on the other of both opposing sides in the column direction of the light-emitting areas R₁₂ₐ, W₁₂ₐ, B₁₂ₐ, and G₁₂ₐ. In addition, the driving circuits R_{23b}, W_{23b}, B_{23b}, and G_{23b} of the first to fourth sub-pixels R₂₃, W₂₃, B₂₃, and G₂₃ of the pixel disposed in the third column of the second row are disposed on one of both opposing sides in the column direction of the light-emitting areas R₂₃ₐ, W₂₃ₐ, B₂₃ₐ, and G₂₃ₐ, respectively.

For example, when the gate signal is applied via the third gate line GL3 in a state in which the data voltage is being supplied, the sub-pixels of the pixel disposed in the second column of the first row is sensed.

For example, when the gate signal is applied via the third gate line GL3 in a state in which the data voltage is being supplied, the first sub-pixel R₁₂ of the pixel disposed in the second column of the first row is sensed.

Thereafter, when the gate signal is applied via the third gate line GL3 in a state in which the data voltage is being supplied, the second sub-pixel W₁₂ of the pixel disposed in the second column of the first row is sensed.

Thereafter, when the gate signal is applied via the third gate line GL3 in a state in which the data voltage is being supplied, the third sub-pixel B₁₂ of the pixel disposed in the second column of the first row is sensed.

Thereafter, when the gate signal is applied via the third gate line GL3 in a state in which the data voltage is being supplied, the fourth sub-pixel G₁₂ of the pixel disposed in the second column of the first row is sensed.

As described above, since a data signal corresponding to one gate signal is required for the reference voltage line during one sensing, a total of 12 times of scans are required to sense pixels (a total of 20 sub-pixels) disposed in five columns of one row.

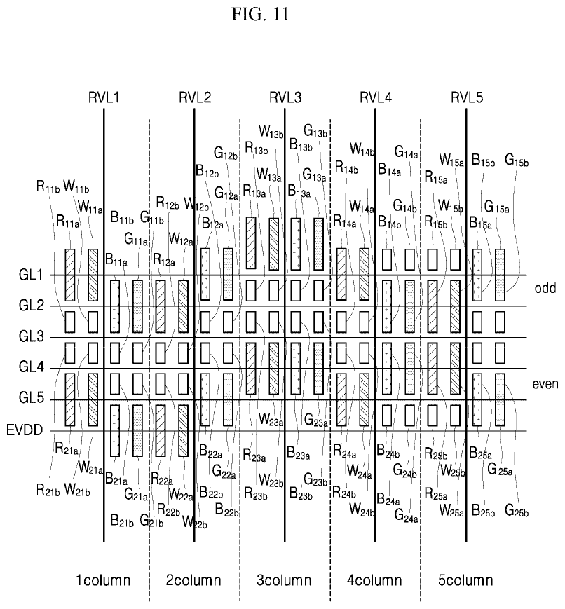

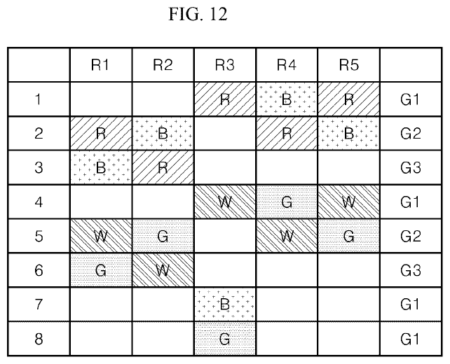

FIG. 11 is a second example diagram illustrating an arrangement of a light-emitting area and a driving circuit of each sub-pixel of a display panel according to one or more embodiments of the present disclosure. FIG. 12 is an example diagram illustrating a sensing sequence of a plurality of sub-pixels in FIG. 11 in a table manner.

Referring to FIG. 11, each sub-pixel of the display panel 110 may include a light-emitting area and a driving circuit for controlling light emission of the light-emitting area. Such a driving circuit may be disposed on one or the other of both opposing sides in the column direction of the corresponding light-emitting area. For example, the driving circuits R_{11b}, W_{11b}, B_{11b}, and G_{11b} of the first to fourth sub-pixels R₁₁, W₁₁, B₁₁, and G₁₁ of the pixel disposed in the first column of the first row are disposed on the other of both opposing sides in the column direction of each of the light-emitting areas R₁₁ₐ, W₁₁ₐ, B₁₁ₐ, and G₁₁ₐ. In addition, the driving circuit of each sub-pixel disposed in each pixel PX may be disposed on one or the other of both opposing sides in the column direction of the corresponding light-emitting area. Thus, the display panel 110 according to the present disclosure is not limited thereto.

As one example, each of a first reference voltage line RVL1 to a fifth reference voltage line RVL5 is disposed inside each of a pixel of a first column to a pixel of a fifth column, but is not limited thereto. For example, each reference voltage line may be disposed between the sub-pixels of each pixel, but is not limited thereto.

According to one or more embodiments, a plurality of reference voltage lines are disposed in the display panel 110, for example, the first reference voltage line RVL1 is disposed inside a pixel of a first column (e.g., between a second sub-pixel and a third sub-pixel of each pixel), the second reference voltage line RVL2 is disposed inside a pixel of a second column (e.g., between a second sub-pixel and a third sub-pixel of each pixel), the third reference voltage line RVL3 is disposed inside a pixel of a third column (e.g., between a second sub-pixel and a third sub-pixel of each pixel), the fourth reference voltage line RVL 4 is disposed inside a pixel of a fourth column (e.g., between a second sub-pixel and a third sub-pixel of each pixel), and the fifth reference voltage line RVL 5 is disposed inside a pixel of a fifth column (e.g., between a second sub-pixel and a third sub-pixel). However, embodiments of the present disclosure are not limited thereto.

According to one or more embodiments, the first gate line GL1 is disposed between the driving circuit R_{13b}, W_{13b}, B_{13b}, and G_{13b} and the light-emitting areas R₁₃ₐ, W₁₃ₐ, B₁₃ₐ, and G₁₃ₐ of the first to fourth sub-pixels R₁₃, W₁₃, B₁₃, and G₁₃ of the pixel disposed in the third column of the first row odd. In addition, the first gate line GL1 is disposed between the light-emitting areas B₁₄ₐ and G₁₄ₐ and the driving circuits B_{14b} and G_{14b} of the third and fourth sub-pixels B₁₄ and G₁₄ of the pixel disposed in the fourth column of the first row, and is disposed between the light-emitting areas R₁₅ₐ and W₁₅ₐ and the driving circuits R_{15b} and W_{15b} of the first and second sub-pixels R₁₅ and W₁₅ of the pixel disposed in the fifth column of the first row.

The driving circuits R_{13b}, W_{13b}, B_{13b}, and G_{13b} of the first to fourth sub-pixels R₁₃, W₁₃, B₁₃, and G₁₃ of the pixel disposed in the third column of the first row are respectively disposed on the other of both opposing sides in the column direction of the light-emitting areas R₁₃ₐ, W₁₃ₐ, B₁₃ₐ, and G₁₃ₐ. In addition, the driving circuits B_{14b} and G_{14b} of the third sub-pixel B₁₄ and the fourth sub-pixel G₁₄ of the pixel disposed in the fourth column of the first row are respectively disposed on one of both opposing sides in the column direction of the light-emitting areas B₁₄ₐ and G₁₄ₐ, while the driving circuits R_{15b} and W_{15b} of the first sub-pixel R₁₅ and the second sub-pixel W₁₅ of the pixel disposed in the fifth column of the first row are respectively disposed on one of both opposing sides in the column direction of the light-emitting areas R₁₅ₐ and W₁₅ₐ.

According to one or more embodiments, the second gate line GL2 is disposed between the light-emitting areas R₁₁ₐ and W₁₁ₐ and the driving circuits R_{11b} and W_{11b} of the first sub-pixel R₁₁ and the second sub-pixel W₁₁ of the pixel disposed in the first column of the first row. In addition, the second gate line GL2 is disposed between the light-emitting areas B₁₂ₐ and G₁₂ₐ and the driving circuits B_{12b} and G_{12b} of the third sub-pixel B₁₂ and the fourth sub-pixel G₁₂ of the pixel disposed in the second column of the first row. In addition, the second gate line GL2 is disposed between the light-emitting areas R₁₄ₐ and W₁₄ₐ and the driving circuits R_{14b} and W_{14b} of the first sub-pixel R₁₄ and the second sub-pixel W₁₄ of the pixel disposed in the fourth column of the first row. In addition, the second gate line GL2 is disposed between the light-emitting areas B₁₅ₐ and G₁₅ₐ and the driving circuits B_{15b} and G_{15b} of the third sub-pixel B₁₅ and the fourth sub-pixel G₁₅ of the pixels SP disposed in the fifth column of the first row.

The driving circuits R_{11b} and W_{11b} of the first sub-pixel R₁₁ and the second sub-pixel W₁₁ of the pixel disposed in the first column of the first row are disposed on the other of both opposing sides in the column direction of the light-emitting areas R₁₁ₐ and W₁₁ₐ, respectively. In addition, the driving circuits B_{12b} and G_{12b} of the third sub-pixel B₁₂ and the fourth sub-pixel G₁₂ of the pixel disposed in the second column of the first row are disposed on the other of both opposing sides in the column direction of the light-emitting areas B₁₂ₐ and G₁₂ₐ. In addition, the driving circuits R_{14b} and W_{14b} of the first sub-pixel R₁₄ and the second sub-pixel W₁₄ of the pixel disposed in the fourth column of the first row are respectively disposed on the other of both opposing sides in the column direction of the light-emitting areas R₁₄ₐ and W₁₄ₐ. In addition, the driving circuits B_{15b} and G_{15b} of the third sub-pixel B₁₅ and the fourth sub-pixel G₁₅ of the pixel disposed in the fifth column of the first row are disposed on the other of both opposing sides in the column direction of the light-emitting areas B₁₅ₐ and G₁₅ₐ, respectively.

According to one or more embodiments, the third gate line GL3 is disposed between the light-emitting areas B₁₁ₐ and G₁₁ₐ and the driving circuits B_{11b} and G_{11b} of the third sub-pixel B₁₁ and the fourth sub-pixel G₁₁ of the pixel disposed in the first column of the first row. In addition, the third gate line GL3 is disposed between the light-emitting areas R₁₂ₐ and W₁₂ₐ and the driving circuits R_{12b} and W_{12b} of the first and second sub-pixels R₁₂ and W₁₂ of the pixel disposed in the second column of the first row. In addition, the third gate line GL3 is disposed between the driving circuits R_{23b}, W_{23b}, B_{23b}, and G_{23b} and the light-emitting areas R₂₃ₐ, W₂₃ₐ, B₂₃ₐ, and G₂₃ₐ of the first to fourth sub-pixels R₂₃, W₂₃, B₂₃, and G₂₃ of the pixel disposed in the third column of the second row even.

The driving circuits B_{11b} and G_{11b} of the third sub-pixel B₁₁ and the fourth sub-pixel G₁₁ of the pixel disposed in the first column of the first row are disposed on the other of both opposing sides in the column direction of the light-emitting areas B₁₁ₐ and G₁₁ₐ, respectively. The driving circuits R_{12b} and W_{12b} of the first sub-pixel R₁₂ and the second sub-pixel W₁₂ of the pixel disposed in the second column of the first row are disposed on the other of both opposing sides in the column direction of the light-emitting areas R₁₂ₐ and W₁₂ₐ, respectively. In addition, the driving circuits R_{23b}, W_{23b}, B_{23b}, and G_{23b} of the first to fourth sub-pixels R₂₃, W₂₃, B₂₃, and G₂₃ of the pixel disposed in the third column of the second row even are respectively disposed on one of both opposing sides in the column direction of the light-emitting areas R₂₃ₐ, W₂₃ₐ, B₂₃ₐ, and G₂₃ₐ.

According to one or more embodiments, the fourth gate line GL4 is disposed between the light-emitting areas R₂₁ₐ and W₂₁ₐ and the driving circuits R_{21b} and W_{21b} of the first sub-pixel R₂₁ and the second sub-pixel W₂₁ of the pixel disposed in the first column of the second row even. In addition, the fourth gate line GL4 is disposed between the light-emitting areas B₂₂ₐ and G₂₂ₐ and the driving circuits B_{22b} and G_{22b} of the third sub-pixel B₂₂ and the fourth sub-pixel G₂₂ of the pixel disposed in the second column of the second row. In addition, the fourth gate line GL4 is disposed between the light-emitting areas R₂₄ₐ and W₂₄ₐ and the driving circuits R_{24b} and W_{24b} of the first and second sub-pixels R₂₄ and W₂₄ of the pixel disposed in the fourth column of the second row even. In addition, the fourth gate line GL4 is disposed between the light-emitting areas B₂₅ₐ and G₂₅ₐ and the driving circuits B_{25b} and G_{25b} of the third and fourth sub-pixels B₂₅ and G₂₅ of the pixel disposed in the fifth column of the second row even.

The driving circuits R_{21b} and W_{21b} of the first sub-pixel R₂₁ and the second sub-pixel W₂₁ of the pixel disposed in the first column of the second row even are disposed on one of both opposing sides in the column direction of the light-emitting areas R₂₁ₐ and W₂₁ₐ, respectively. In addition, the driving circuits G_{22b} and G_{22b} of the third sub-pixel B₂₂ and the fourth sub-pixel G₂₂ of the pixel disposed in the second column of the second row are disposed on one of both opposing sides in the column direction of the light-emitting areas B₂₂ₐ and G₂₂ₐ, respectively. In addition, the driving circuits R_{24b} and W_{24b} of the first sub-pixel R₂₄ and the second sub-pixel W₂₄ of the pixel disposed in the fourth column of the second row even are disposed on one of both opposing sides in the column direction of the light-emitting areas R₂₄ₐ and W₂₄ₐ, respectively. In addition, the driving circuits B_{25b} and G_{25b} of the third sub-pixel B₂₅ and the fourth sub-pixel G₂₅ of the pixel disposed in the fifth column of the second row even are disposed on one of both opposing sides in the column direction of the light-emitting areas B₂₅ₐ and G₂₅ₐ, respectively.

According to one or more embodiments, the fifth gate line GL5 is disposed between the light emission areas B₂₁ₐ and G₂₁ₐ and the driving circuits B_{21b} and G_{21b} of the third sub-pixel B₂₁ and the fourth sub-pixel G₂₁ of the pixel disposed in the first column of the second row even. In addition, the fifth gate line GL5 is disposed between the light-emitting areas R₂₂ₐ and W₂₂ₐ and the driving circuits R_{22b} and W_{22b} of the first and second sub-pixel R₂₂ and W₂₂ of the pixel disposed in the second column of the second row even. In addition, the fifth gate line GL5 is disposed between the light-emitting areas B₂₄ₐ and G₂₄ₐ and the driving circuits B_{24b} and G_{24b} of the third and fourth sub-pixels B₂₄ and G₂₄ of the pixel disposed in the fourth column of the second row even. In addition, the fifth gate line GL5 is disposed between the light-emitting areas R₂₅ₐ and W₂₅ₐ and the driving circuits R_{25b} and W_{25b} of the first sub-pixel R₂₅ and the second sub-pixel W₂₅ of the pixel disposed in the fifth column of the second row even.

The driving circuits B_{21b} and G_{21b} of the third sub-pixel B₂₁ and the fourth sub-pixel G₂₁ of the pixel disposed in the first column of the second row even are disposed on one of both opposing sides in the column direction of the light-emitting areas B₂₁ₐ and G₂₁ₐ, respectively. In addition, the driving circuits R_{22b} and W_{22b} of the first sub-pixel R₂₂ and the second sub-pixel W₂₂ of the pixel disposed in the second column of the second row even are disposed on one of both opposing sides in the column direction of the light-emitting areas R₂₂ₐ and W₂₂ₐ, respectively. In addition, the driving circuits B_{24b} and G_{24b} of the third sub-pixel B₂₄ and the fourth sub-pixel G₂₄ of the pixel disposed in the fourth column of the second row even are disposed on the other of both opposing sides in the column direction of the light-emitting areas B₂₄ₐ and G₂₄ₐ. In addition, the driving circuits R_{25b} and W_{25b} of the first sub-pixel R₂₅ and the first sub-pixel W₂₅ of the pixel disposed in the fifth column of the second row even are disposed on the other of both opposing sides in the column direction of the light-emitting areas R₂₅ₐ and W₂₅ₐ.

According to one or more embodiments, an additional high potential voltage line EVDD is disposed on the other of both opposing sides in the column direction of the fifth gate line GL 5. A single additional high potential voltage line EVDD is disposed every the five gate lines GL1 to GL5.

Referring to FIG. 12, a sensing sequence of two sub-pixels in pixels arranged in a first row in an arrangement structure of a light-emitting area and a driving circuit of each sub-pixel according to FIG. 11 will be described.

According to one or more embodiments, when the gate signal is applied via the first gate line GL1 in a state in which the data voltage is being supplied, the first sub-pixel R₁₃ of the pixel disposed in the third column of the first row, the third sub-pixel B₁₄ disposed in the fourth column of the first row, and the first sub-pixel R₁₅ disposed in the fifth column of the first row are sensed.

Due to this arrangement, a total of three sub-pixels are sensed at the first sensing.

Thereafter, when the gate signal is applied via the second gate line GL2 while the data voltage is being supplied, the first sub-pixel R₁₁ of the pixel disposed in the first column of the first row, the third sub-pixel B₁₂ disposed in the second column of the first row, the first sub-pixel R₁₄ disposed in the fourth column of the first row, and the third sub-pixel B₁₅ disposed in the fifth column of the first row are sensed.

Due to this arrangement, a total of four sub-pixels are sensed at the second sensing.

Thereafter, when the gate signal is applied via the third gate line GL3, the third sub-pixel B₁₁ of the pixel disposed in the first column of the first row and the first sub-pixel R₁₂ of the pixel disposed in the second column of the first row are sensed.

Due to this arrangement, a total of two sub-pixels are sensed at the third sensing.

Thereafter, when the gate signal is applied via the first gate line GL1 while the data voltage is being supplied, the second sub-pixel W₁₃ of the pixel disposed in the third column of the first row, the fourth sub-pixel G₁₄ of the pixel disposed in the fourth column of the first row, and the second sub-pixel W₁₅ of the pixel disposed in the fifth column of the first row are sensed.

Due to this arrangement, a total of three sub-pixels are sensed at the fourth sensing.

Thereafter, when the gate signal is applied via the second gate line GL2 in a state in which the data voltage is being supplied, the second sub-pixel W₁₁ of the pixel disposed in the first column of the first row, the fourth sub-pixel G₁₂ of the pixel disposed in the second column of the first row, the second sub-pixel W₁₄ of the pixel disposed in the fourth column of the first row, and the fourth sub-pixel G₁₅ of the pixel disposed in the fifth column of the first row are sensed.

Due to this arrangement, a total of four sub-pixels are sensed at the fifth sensing.

Thereafter, when the gate signal is applied via the third gate line GL3 in a state in which the data voltage is being supplied, the fourth sub-pixel G₁₁ of the pixel disposed in the first column of the first row and the second sub-pixel W₁₂ of the pixel disposed in the second column of the first row are sensed.

Due to this arrangement, a total of two sub-pixels are sensed at the sixth sensing.

Thereafter, when the gate signal is applied via the first gate line GL1 in a state in which the data voltage is being supplied, the third sub-pixel B₁₃ of the pixel disposed in the third column of the first row is sensed.

Due to this arrangement, a total of one sub-pixel are sensed at the seventh sensing.

Thereafter, when the gate signal is applied via the first gate line GL1 in a state in which the data voltage is being supplied, the fourth sub-pixel G₁₃ of the pixel disposed in the third column of the first row is sensed.

Due to this arrangement, a total of one sub-pixel are sensed at the eighth sensing.

As described above, it takes a total of eight times of scans to sense the sub-pixels (a total of 20 sub-pixels) of four pixels arranged in one row.

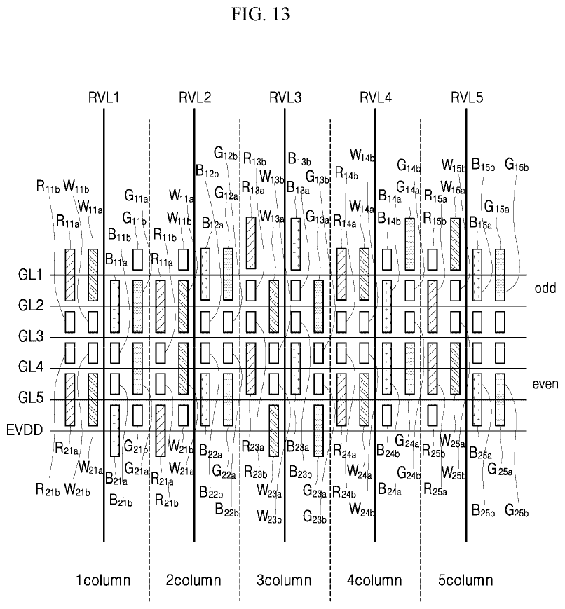

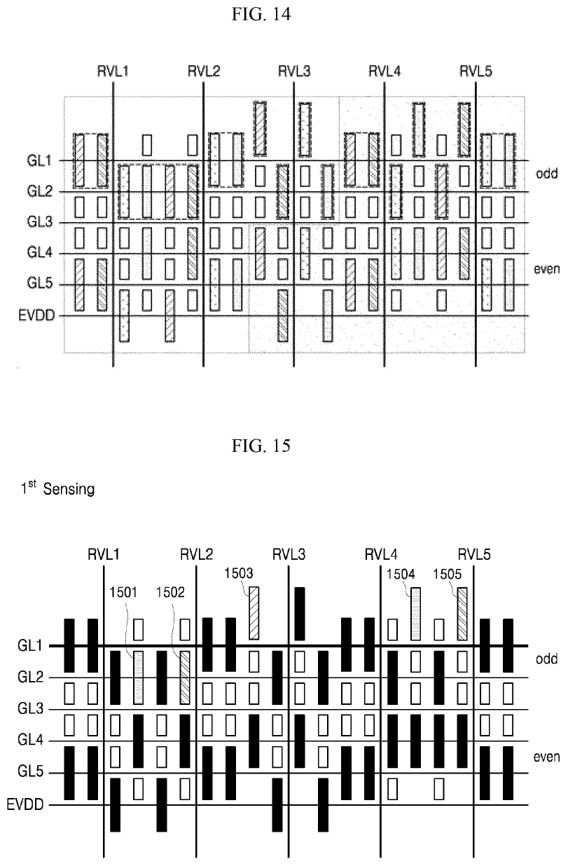

FIG. 13 is a third example diagram illustrating an arrangement of a light-emitting area and a driving circuit of each sub-pixel of a display panel according to one or more embodiments of the present disclosure. FIG. 14 is an example diagram illustrating sub-pixels of FIG. 13 which are grouped into groups on a data basis.

In the description of FIG. 13, the same contents as those as described above with reference to FIG. 11 will be omitted or briefly given for convenience of description.

As one example, each of a first reference voltage line RVL1 to a fifth reference voltage line RVL5 is disposed inside each of a pixel of a first column to a pixel of a fifth column, but is not limited thereto. For example, each reference voltage line may be disposed between the sub-pixels of each pixel, but is not limited thereto.

According to an embodiment, a plurality of reference voltage lines are disposed in the display panel 110, for example, the first reference voltage line RVL1 is disposed inside a pixel of a first column (e.g., between a second sub-pixel and a third sub-pixel of each pixel), the second reference voltage line RVL2 is disposed inside a pixel of a second column (e.g., between a second sub-pixel and a third sub-pixel of each pixel), the third reference voltage line RVL3 is disposed inside a pixel of a third column (e.g., between a second sub-pixel and a third sub-pixel of each pixel), the fourth reference voltage line RVL 4 is disposed inside a pixel of a fourth column (e.g., between a second sub-pixel and a third sub-pixel of each pixel), and the fifth reference voltage line RVL5 is disposed inside a pixel of a fifth column (e.g., between a second sub-pixel and a third sub-pixel). However, embodiments of the present disclosure are not limited thereto.

According to one or more embodiments, the first gate line GL1 is disposed between the light-emitting area G₁₁ₐ and the driving circuit G_{13b} of the fourth sub-pixel G₁₁ of the pixel disposed in the first column of the first row odd, between the light-emitting area W₁₂ₐ and the driving circuit W_{12b} of the second sub-pixel W₁₂ of the pixel disposed in the second column of the first row odd, between the light-emitting area R₁₃ₐ and the driving circuit R_{13b} of the first sub-pixel R₁₃ of the pixel disposed in the third column of the first row odd, and between the light-emitting area B₁₃ₐ and the driving circuit B_{13b} of the third sub-pixel B₁₃ of the pixel disposed in the third column of the first row odd.

In addition, the first gate line GL1 may be disposed between the light-emitting areas and the driving circuits of the third sub-pixel B₁₄ and the fourth sub-pixel G₁₄ of the pixel disposed in the fourth column, between the light-emitting areas and the driving circuits of the first sub-pixel R₁₅ and the second sub-pixel W₁₅ of the pixel disposed in the fifth column, but is not limited thereto.

For example, the first gate line GL1 is disposed between the light-emitting area B₁₄ₐ and the driving circuit B_{14b} of the third sub-pixel B₁₄ of the pixel disposed in the fourth column, between the light-emitting area G₁₄ₐ and the driving circuit G_{14b} of the fourth sub-pixel G₁₄ of the pixel disposed in the fourth column, between the light-emitting area R₁₅ₐ and the driving circuit R_{15b} of the first sub-pixel R₁₅ of the pixel disposed in the fifth column, and between the light-emitting area W₁₅ₐ and the driving circuit W_{15b} of the second sub-pixel W₁₅ of the pixel disposed in the fifth column.

The driving circuits G_{11b}, W_{12b}, B_{14b}, and R_{15b} of the fourth sub-pixel G₁₁ of the pixel disposed in the first column of the first row odd, the second sub-pixel W₁₂ of the pixel disposed in the second column of the first row odd, the third sub-pixel B₁₄ of the pixel disposed in the fourth column of the first row odd, and the first sub-pixel R₁₅ of the pixel disposed in the fifth column of the first row odd are disposed on one of both opposing sides in the column direction of the light-emitting areas G₁₁ₐ, W₁₂ₐ, B₁₄ₐ, and R₁₅ₐ, respectively.

In addition, the driving circuits R_{13b}, B_{13b}, G_{14b}, and W_{15b} of the first sub-pixel R₁₃, the third sub-pixel B₁₃, the fourth sub-pixel G₁₄ of the pixel disposed in the fourth column, and the second sub-pixel W₁₅ of the pixel disposed in the fifth column which are disposed in the third column of the first row odd are respectively disposed on one of both opposing sides in the column direction of the light-emitting areas R₁₃ₐ, B₁₃ₐ, G₁₄ₐ, and W₁₅ₐ.

According to one or more embodiments, the second gate line GL2 is disposed between the light-emitting areas R₁₁ₐ and W₁₁ₐ and the driving circuits R_{11b} and W_{11b} of the first and second sub-pixel R₁₁ and W₁₁ of the pixel disposed in the first column of the first row odd, between the light-emitting area B₁₂ₐ and the driving circuit B_{12b} of the third sub-pixel B₁₂ of the pixel disposed in the second column of the first row odd, and between the light-emitting area G₁₂ₐ of the fourth sub-pixel G₁₂ and the driving circuit G_{12b} of the pixel disposed in the second column. In addition, the second gate line GL2 may be disposed between the light-emitting areas and the driving circuits of the first sub-pixel R₁₄ and the second sub-pixel W₁₄ of the pixel disposed in the fourth column, between the light-emitting areas and the driving circuits of the third sub-pixel B₁₅ and the fourth sub-pixel G₁₅ of the pixel disposed in the fifth column, but is not limited thereto.

For example, the second gate line GL2 is disposed between the light-emitting area R₁₄ₐ and the driving circuit R_{14b} of the first sub-pixel R₁₄ of the pixel disposed in the fourth column, between the light-emitting area W₁₄ₐ and the driving circuit W_{14b} of the second sub-pixel W₁₄ of the pixel disposed in the fourth column, between the light-emitting area B₁₅ₐ and the driving circuit B_{15b} of the third sub-pixel B₁₅ of the pixel disposed in the fifth column, and between the light-emitting area G₁₅ₐ and the driving circuit G_{15b} of the fourth sub-pixel G₁₅ of the pixel disposed in the fifth column.

The driving circuits R_{11b}, W_{11b}, B_{12b}, G_{12b}, R_{14b}, W_{14b}, B_{15b}, and G_{15b} of the first sub-pixel R₁₁ and the second sub-pixel W₁₁ of the pixel disposed in the first column of the first row, the third sub-pixel B₁₂ and the fourth sub-pixel G₁₂ of the pixel disposed in the second column of the first row, the first sub-pixel R₁₄ and the second sub-pixel W₁₄ of the pixel disposed in the fourth column of the first row, and the third sub-pixel B₁₅ and the fourth sub-pixel G₁₅ of the pixel disposed in the fifth column of the first row are respectively disposed on the other of both opposing sides in the column direction of the light-emitting areas R₁₁ₐ, W₁₁ₐ, B₁₂ₐ, G₁₂ₐ, R₁₄ₐ, W₁₄ₐ, B₁₅ₐ, and G₁₅ₐ.

According to one or more embodiments, the third gate line GL3 is disposed between the light-emitting area B₁₁ₐ and the driving circuit B_{11b} of the third sub-pixel B₁₁ of the pixel disposed in the first column of the first row odd, and is disposed between the light-emitting area R₁₂ₐ and the driving circuit R_{12b} of the first sub-pixel R₁₂ of the pixel disposed in the second column of the first row odd. In addition, the third gate line GL3 is disposed between the light-emitting area R₂₃ₐ of the first sub-pixel R₂₃ and the driving circuit R_{23b} of the pixel disposed in the third column of the second row even. In addition, the third gate line GL3 is disposed between the light-emitting area W₁₃ₐ and the driving circuit W_{13b} of the second sub-pixel W₁₃ disposed in the third column of the first row odd, between the light-emitting area B₂₃ₐ and the driving circuit B_{23b} of the third sub-pixel B₂₃ disposed in the third column of the second row even, between the light-emitting area G₁₃ₐ and the driving circuit G_{13b} of the fourth sub-pixel G₁₃ disposed in the third column of the first row odd, between the light-emitting area G₂₄ₐ and the driving circuit G_{24b} of the fourth sub-pixel G₂₄ disposed in the fourth column of the second row even, and is disposed between the light-emitting area W₂₅ₐ and the driving circuit W_{25b} of the second sub-pixel W₂₅ of the pixel disposed in the fifth column of the second row even.

The driving circuits B_{11b}, R_{12b}, W_{23b}, and G_{13b} of the third sub-pixel B₁₁ of the pixel disposed in the first column of the first row odd, the first sub-pixel R₁₂ of the pixel disposed in the second column of the first row odd, and the second sub-pixel W₂₃ and the fourth sub-pixel G₁₃ of the pixel disposed in the third column of the first row odd are disposed on the other of both opposing sides in the column direction of the light-emitting areas B₁₁ₐ, R₁₂ₐ, W₂₃ₐ, and G₁₃ₐ, respectively.

In addition, the driving circuits R_{23b}, B_{23b}, G_{24b}, and W_{23b} of the first sub-pixel R₂₃ and the third sub-pixel B₂₃ of the pixel disposed in the third column of the second row even, the fourth sub-pixel G₂₄ of the pixel disposed in the fourth column of the second row even, and the second sub-pixel W₂₃ of the pixel disposed in the fifth column of the second row even are respectively disposed on one of both opposing sides in the column direction of the light-emitting areas R₂₃ₐ, B₂₃ₐ, G₂₄ₐ, and W₂₃ₐ.

According to one or more embodiments, the fourth gate line GL4 is disposed between the light-emitting areas R₂₁ₐ and W₂₁ₐ and the driving circuit R_{21b} and W_{21b} of the first and second sub-pixel R₂₁ and W₂₁ of the pixel disposed in the first column of the second row even, and between the light-emitting areas B₂₂ₐ and G₂₂ₐ and the driving circuit B_{22b} and G_{22b} of the third sub-pixel B₂₂ and the fourth sub-pixel G₂₂ of the pixel disposed in the second column of the second row even. In addition, the fourth gate line GL4 is disposed between the light-emitting areas R₂₄ₐ and W₂₄ₐ and the driving circuits R_{24b} and W_{24b} of the first sub-pixel R₂₄ and the second sub-pixel W₂₄ of the pixel disposed in the fourth column of the second row even. In addition, the fourth gate line GL4 is disposed between the light-emitting areas B₂₅ₐ and G₂₅ₐ and the driving circuits B_{25b} and G_{25b} of the third and fourth sub-pixels B₂₅ and G₂₅ of the pixel disposed in the fifth column of the second row even.

The driving circuits R_{21b}, W_{21b}, B_{22b}, G_{22b}, R_{24b}, W_{24b}, B_{25b}, and G_{25b} of the first sub-pixel R₂₁ and the second sub-pixel W₂₁ of the pixel disposed in the first column of the second row even, the third sub-pixel B₂₂ and the fourth sub-pixel G₂₂ of the pixel disposed in the second column of the second row even, the first sub-pixel R₂₄ and the second sub-pixel W₂₄ of the pixel disposed in the fourth column of the second row even, and the third sub-pixel B₂₅ and the fourth sub-pixel G₂₅ of the pixel disposed in the fifth column of the second row even are respectively disposed on one of both opposing sides in the column direction of the light-emitting areas R₂₁ₐ, W₂₁ₐ, B₂₂ₐ, G₂₂ₐ, R₂₄ₐ, W₂₄ₐ, B₂₅ₐ, G₂₅ₐ.

According to one or more embodiments, the fifth gate line GL5 is disposed between the light-emitting areas B₂₁ₐ and G₂₁ₐ and the driving circuit B_{21b} and G_{21b} of the third and fourth sub-pixels B₂₁ and G₂₁ of the pixel disposed in the first column of the second row even, between the light-emitting areas R₂₂ₐ and W₂₂ₐ and the driving circuit R_{22b} and W_{22b} of the first sub-pixel R₂₂ and the second sub-pixel W₂₂ disposed in the second column of the second row even, between the light-emitting areas W₂₃ₐ and G₂₃ₐ and the driving circuit W_{23b} and G_{23b} of the second sub-pixel W₂₃ and the fourth sub-pixel G₂₃ disposed in the third column of the second row even, and between the light-emitting areas B₂₄ₐ and the driving circuit B_{24b} of the third sub-pixel B₂₄ disposed in the fourth column of the second row even, and between the light-emitting area R₂₅ₐ and the driving circuit R_{25b} of the first sub-pixel R₂₅ of the pixel disposed in the fifth column of the second row even.

The driving circuits B_{22b}, R_{22b}, W_{23b}, and G_{24b} of the third sub-pixel B₂₂ of the pixel disposed in the first column of the second row even, the first sub-pixel R₂₂ of the pixel disposed in the second column of the second row even, and the second sub-pixel W₂₃ and the fourth sub-pixel G₂₄ of the pixel disposed in the third column of the second row even are respectively disposed on one of both opposing sides in the column direction of the light-emitting areas B₂₂ₐ, R₂₂ₐ, W₂₃ₐ, and G₂₄ₐ.

In addition, the driving circuits G_{21b}, W_{22b}, B_{24b}, and R_{25b} of the fourth sub-pixel G₂₁ of the pixel disposed in the first column, the second sub-pixel W₂₂ of the pixel disposed in the second column of the second row even, the third sub-pixel B₂₄ of the pixel disposed in the fourth column of the second row even, and the first sub-pixel R₂₅ of the pixel disposed in the fifth column of the second row even are respectively disposed on the other of both opposing sides in the column direction of the light-emitting areas G₂₁ₐ, W₂₂ₐ, B₂₄ₐ, and R₂₅ₐ.

As illustrated in FIG. 14, the sub-pixels SP illustrated in FIG. 13 may be grouped into the groups on a data basis.

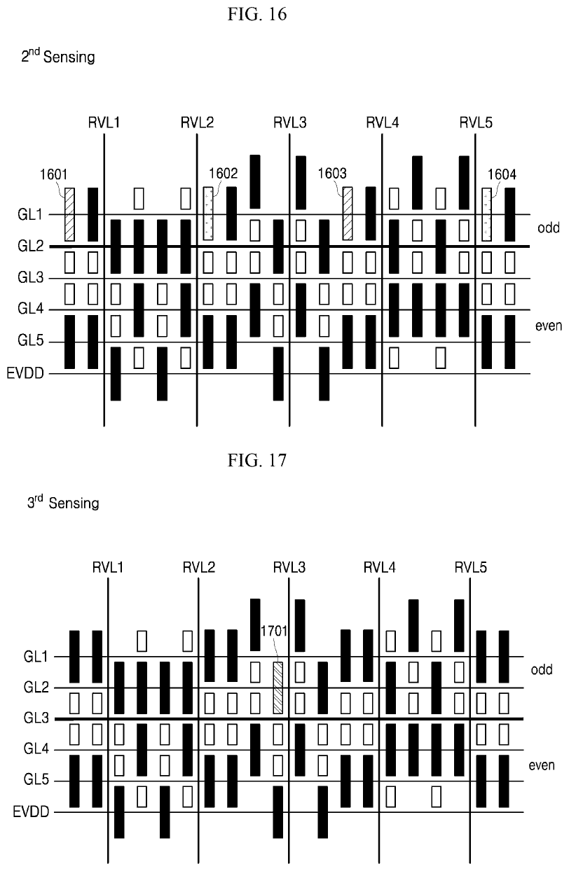

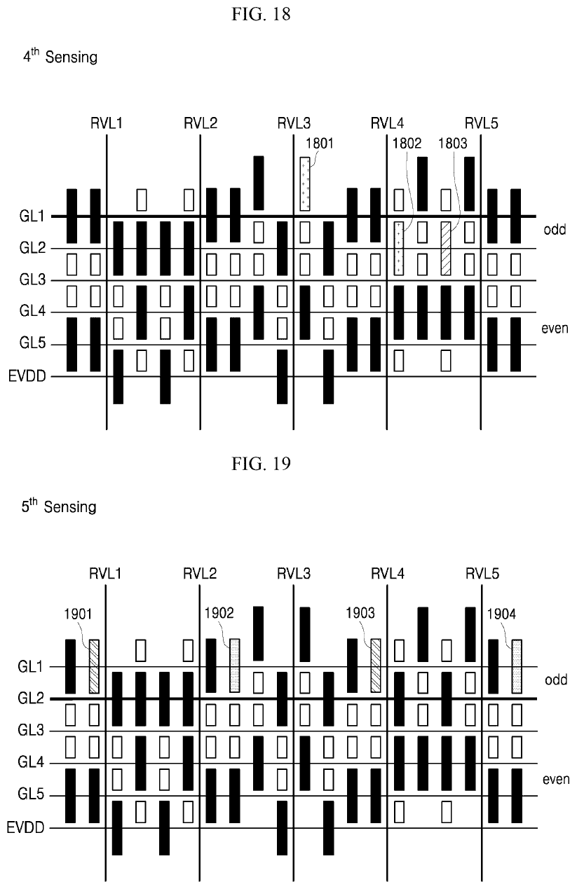

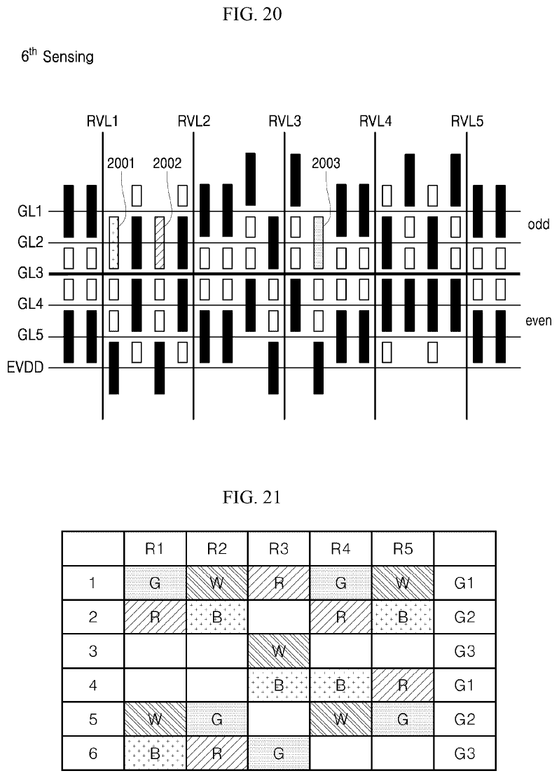

FIG. 15 is an example diagram illustrating a sensing state of a sub-pixel disposed in a first row according to a first sensing in the display panel shown in FIG. 13. FIG. 16 is an example diagram illustrating a sensing state of a sub-pixel according to a second sensing after FIG. 15. FIG. 17 is an example diagram illustrating a sensing state of a sub-pixel according to a third sensing after FIG. 16. FIG. 18 is an example diagram illustrating a sensing state of a sub-pixel according to a fourth sensing after FIG. 17. FIG. 19 is an example diagram illustrating a sensing state of a sub-pixel according to a fifth sensing after FIG. 18. FIG. 20 is an example diagram illustrating a sensing state of a sub-pixel according to a sixth sensing after FIG. 19. FIG. 21 is an example diagram illustrating a plurality of sub-pixels that emit light according to the first to sixth sensing in FIGS. 15 to 20 in a table manner.

In describing the sub-pixels SPX illustrated in FIGS. 15 to 20, descriptions duplicate with those as set forth above with reference to FIG. 13 will be omitted or briefly given. In addition, although FIGS. 15 to 20 illustrate emission states of the sub-pixels of the pixels arranged in the first row, it is obvious that the emission states may be applied to the other rows in the same or similar manner.

Referring to FIG. 15, when the gate signal is applied via the first gate line GL1 in a state in which the data voltage is being supplied, the fourth sub-pixel G 1501 of the pixel disposed in the first column, the second sub-pixel W 1502 of the pixel disposed in the second column, the first sub-pixel R 1503 of the pixel disposed in the third column, the fourth sub-pixel G 1504 of the pixel disposed in the fourth column, and the second sub-pixel W 1505 of the pixel disposed in the fifth column are sensed.

The driving circuit of the fourth sub-pixel G 1501 of the pixel disposed in the first column is disposed on one of both opposing sides in the column direction of the corresponding light-emitting area. The driving circuit of the second sub-pixel W 1502 of the pixel disposed in the second column is disposed on one of both opposing sides in the column direction of the corresponding light-emitting area. In addition, the driving circuit of the first sub-pixel R 1503 of the pixel disposed in the third column is disposed on the other of both opposing sides in the column direction of the corresponding light-emitting area. The driving circuit of the fourth sub-pixel G 1504 of the pixel disposed in the fourth column is disposed on the other of both opposing sides in the column direction of the corresponding light-emitting area. The driving circuit of the second sub-pixel W 1505 of the pixel disposed in the fifth column are disposed on the other of both opposing sides in the column direction of the corresponding light-emitting area.

Due to this arrangement, a total of five sub-pixels are sensed at the first sensing.

Referring to FIG. 16, when the gate signal is applied via the second gate line GL2 in a state in which the data voltage is being supplied, the first sub-pixel R 1601 of the pixel disposed in the first column, the third sub-pixel B 1602 of the pixel disposed in the second column, the first sub-pixel R 1603 of the pixel disposed in the fourth column, and the third sub-pixel B 1604 of the pixel disposed in the fifth column are sensed.

The driving circuit of the first sub-pixel R 1601 of the pixel disposed in the first column is disposed on the other of both opposing sides in the column direction of the corresponding light-emitting area. The driving circuit of the third sub-pixel B 1602 of the pixel disposed in the second column is disposed on the other of both opposing sides in the column direction of the corresponding light-emitting area. The driving circuit of the first sub-pixel R 1603 of the pixel disposed in the fourth column is disposed on the other of both opposing sides in the column direction of the corresponding light-emitting area. The driving circuit of the third sub-pixel B 1604 of the pixel disposed in the fifth column is disposed on the other of both opposing sides in the column direction of the corresponding light-emitting area.

Due to this arrangement, a total of four sub-pixels are sensed at the second sensing.

Referring to FIG. 17, when the gate signal is applied via the third gate line GL3 in a state in which the data voltage is being supplied, the second sub-pixel W 1701 of the pixel disposed in the third column is sensed.

The driving circuit of the second sub-pixel W 1701 of the pixel disposed in the third column is disposed on the other of both opposing sides in the column direction of the corresponding light-emitting area. Due to this arrangement, a total of one sub-pixel is sensed at the third sensing.

Referring to FIG. 18, when the gate signal is applied via the first gate line GL1 in a state in which the data voltage is being supplied, the third sub-pixel B 1801 of the pixel disposed in the third column, the third sub-pixel B 1802 of the pixel disposed in the fourth column, and the first sub-pixel R 1803 of the pixel disposed in the fifth column are sensed.

The driving circuit of the third sub-pixel B 1801 of the pixel disposed in the third column is disposed on the other of both opposing sides in the column direction of the light-emitting area. On the other hand, the driving circuit of each of the third sub-pixel B 1802 of the pixel disposed in the fourth column and the first sub-pixel R 1803 of the pixel disposed in the fifth column is disposed on one of both opposing sides in the column direction of the light-emitting area.

Due to this arrangement, a total of three sub-pixels are sensed at the fourth sensing.

Referring to FIG. 19, when the gate signal is applied via the second gate line GL2 while the data voltage is being supplied, the second sub-pixel W 1901 of the pixel disposed in the first column, the fourth sub-pixel G 1902 of the pixel disposed in the second column, the second sub-pixel W 1903 of the pixel disposed in the fourth column, and the fourth sub-pixel G 1904 of the pixel disposed in the fifth column are sensed.

The driving circuit of the second sub-pixel W 1901 of the pixel disposed in the first column is disposed on the other of both opposing sides in the column direction of the corresponding light-emitting area. The driving circuit of the fourth sub-pixel G 1902 of the pixel disposed in the second column is disposed on the other of both opposing sides in the column direction of the corresponding light-emitting area. The driving circuit of the second sub-pixel W 1903 of the pixel disposed in the fourth column is disposed on the other of both opposing sides in the column direction of the corresponding light-emitting area. The driving circuit of the fourth sub-pixel G 1904 of the pixel disposed in the fifth column is disposed on the other of both opposing sides in the column direction of the corresponding light-emitting area.

Due to this arrangement, a total of four sub-pixels are sensed at the fifth sensing.

Referring to FIG. 20, when the gate signal is applied via the third gate line GL3 in a state in which the data voltage is being supplied, the third sub-pixel B 2001 of the pixel disposed in the first column, the first sub-pixel R 2002 of the pixel disposed in the second column, and the fourth sub-pixel G 2003 of the pixel disposed in the third column are sensed.

The driving circuit of the third sub-pixels B 2001 of the pixel disposed in the first column is disposed on the other of both opposing sides in the column direction of the corresponding light-emitting area. The driving circuit of the first sub-pixel R 2002 of the pixel disposed in the second column is disposed on the other of both opposing sides in the column direction of the corresponding light-emitting area. The driving circuit of the fourth sub-pixel G 2003 of the pixel disposed in the third column is disposed on the other of both opposing sides in the column direction of the corresponding light-emitting area.

Due to this arrangement, a total of three sub-pixels are sensed at the sixth sensing.

As described above, in order to compensate for the sub-pixels R, W, B, and G of each of the five pixels PX, the five reference voltage lines RVL1, RVL2, RVL3, RVL4, and RVL5 are used, and at least two sub-pixel is sensed at one scan, such that the sub-pixels of each of the five pixels may be sensed using the six times of sensing. Accordingly, the time required to sense the sub-pixels may be shortened.

As described above, it takes a total of six times of sensing to sense the sub-pixels (a total of 20 sub-pixels) of four pixels arranged in one row.

The display device according to various aspects and embodiments of the present disclosure may be described as follows.

One aspect of the present disclosure provides a display panel configured to drive five pixels arranged in the same row using two data lines, wherein the display panel comprises: a plurality of pixels, each pixel including a plurality of sub-pixels respectively emitting light of different colors; a plurality of data lines disposed to supply a data voltage to the plurality of pixels, wherein each of the plurality of data lines divides into a plurality of sub-data lines; and a plurality of gate lines disposed to supply a gate signal to the plurality of pixels.

In accordance with some embodiments of the display panel, the sub-pixels included in each of the plurality of pixels are arranged so as to be sensed in a multiple manner based on the gate signal being applied the plurality of pixels via the gate line.

In accordance with some embodiments of the display panel, each of the plurality of sub-data lines is constructed such that the data voltage is applied to three or two sub-pixels arranged in a first row via a first sub-data line among the plurality of sub-data lines or the data voltage is applied to two or three sub-pixels arranged in a second row adjacent to the first row in a column direction via the first sub-data line.

In accordance with some embodiments of the display panel, the plurality of pixels include first and second pixels arranged in a first row and adjacent to each other, wherein each of the sub-pixels includes a light-emitting area and a driving circuit, wherein in a plan view of the display panel, the driving circuit of one of the plurality of sub-pixels of each of the first and second pixels of the first row is disposed on one of both opposing sides in a column direction of the light-emitting area of the one of the plurality of sub-pixels of each of the first and second pixels, wherein each of the respective driving circuits of the others of the plurality of sub-pixels of each of the first and second pixels of the first row is disposed on the other of both opposing sides in the column direction of each of the respective light-emitting areas of the others of the plurality of sub-pixels of each of the first and second pixels.

In accordance with some embodiments of the display panel, the plurality of pixels further include a third pixel disposed in the first row and adjacent to the second pixel, wherein the respective driving circuits of all of the plurality of sub-pixels of the third pixel are respectively disposed on the same sides of both opposing sides in the column direction of the respective light-emitting areas of all of the plurality of sub-pixels of the third pixel.

In accordance with some embodiments of the display panel, the plurality of pixels further include a fourth pixel disposed in the first row and adjacent to the third pixel, and a fifth pixel disposed in the first row and adjacent to the fourth pixel, wherein the driving circuit of one of the plurality of sub-pixels of each of the fourth and fifth pixels is disposed on one of both opposing sides in a column direction of the light-emitting area of the one of the plurality of sub-pixels of each of the fourth and fifth pixels, wherein each of the respective driving circuits of the others of the plurality of sub-pixels of each of the fifth and fourth pixels is disposed on the other of both opposing sides in the column direction of each of the respective light-emitting areas of the others of the plurality of sub-pixels of each of the fourth and fifth pixels.

In accordance with some embodiments of the display panel, the first pixel includes: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the fourth sub-pixel is disposed on one of both opposing sides in the column direction of the light-emitting area of the fourth sub-pixel, wherein each of the respective driving circuits of the first to third sub-pixels is disposed on the other of both opposing sides in the column direction of each of the respective light-emitting areas of the first to third sub-pixels.

In accordance with some embodiments of the display panel, the second pixel includes: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the second sub-pixel is disposed on one of both opposing sides in the column direction of the light-emitting area of the second sub-pixel, wherein each of the respective driving circuits of the first, third and fourth sub-pixels is disposed on the other of both opposing sides in the column direction of each of the respective light-emitting areas of the first, third and fourth sub-pixels.

In accordance with some embodiments of the display panel, the third pixel includes: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein each of the respective driving circuits of the first to fourth sub-pixels of the third pixel is disposed on the rsame sides of both opposing sides in the column direction of the respective light-emitting areas of the first to fourth sub-pixels of the third pixel.

In accordance with some embodiments of the display panel, the fourth pixel includes: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the third sub-pixel is disposed on one of both opposing sides in the column direction of the light-emitting area of the third sub-pixel, wherein each of the respective driving circuits of the first, second and fourth sub-pixels is disposed on the other of both opposing sides in the column direction of each of the respective light-emitting areas of the first, second and fourth sub-pixels.

In accordance with some embodiments of the display panel, the fifth pixel includes: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the first sub-pixel is disposed on one of both opposing sides in the column direction of the light-emitting area of the first sub-pixel, wherein each of the respective driving circuits of the second to fourth sub-pixels is disposed on the other of both opposing sides in the column direction of each of the respective light-emitting areas of the second to fourth sub-pixels.

In accordance with some embodiments of the display panel, the plurality of pixels further include a third pixel disposed in the first row and adjacent to the second pixel, wherein the third pixel includes: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the fourth sub-pixel is disposed on one of both opposing sides in the column direction of the light-emitting area of the fourth sub-pixel, wherein each of the respective driving circuits of the first to third sub-pixels is disposed on the other of both opposing sides in the column direction of each of the respective light-emitting areas of the first to third sub-pixels.

In accordance with some embodiments of the display panel, each of the sub-pixels includes a light-emitting area and a driving circuit, wherein the plurality of pixels include first and second pixels respectively disposed in the first row and a second row adjacent to each other in a column direction, wherein the first and second pixels are arranged in the same column, wherein in a plan view of the display panel, the driving circuit of each of the plurality of sub-pixels of the first pixel is disposed on one of both opposing sides in a column direction of the light-emitting area of each of the plurality of sub-pixels of the first pixel, wherein the driving circuit of each of the plurality of sub-pixels of the second pixel aligned with each of the plurality of sub-pixels of the first pixel in the column direction is disposed on the other of both opposing sides in the column direction of the light-emitting area of each of the plurality of sub-pixels of the second pixel aligned with each of the plurality of sub-pixels of the first pixel in the column direction.

In accordance with some embodiments of the display panel, the sub-pixels arranged in each of the first and second pixels include a first group of four sub-pixels consecutively arranged in the row direction, and a second group of four sub-pixels consecutively arranged in the row direction, wherein the first group is adjacent to the second group in the row direction, wherein the driving circuit of each of the sub-pixels of the first group is disposed on one of both opposing sides in a column direction of the light-emitting area of each of the sub-pixels of the first group, wherein the driving circuit of each of the sub-pixels of the second group is disposed on the other of both opposing sides in the column direction of the light-emitting area of each of the sub-pixels of the second group.

In accordance with some embodiments of the display panel, the plurality of pixels include first to fifth pixels sequentially arranged in the first row and adjacent to each other, wherein each of the first to fifth pixels of the first row includes first to fourth sub-pixels sequentially arranged in the row direction and adjacent to each other, wherein the plurality of gate lines include a first gate line, wherein the first gate line is disposed between the driving circuit and the light-emitting area of the fourth sub-pixel of the first pixel, between the driving circuit and the light-emitting area of the second sub-pixel of the second pixel, between the driving circuit and the light-emitting area of each of the first sub-pixel and the third sub-pixel of the third pixel, between the driving circuit and the light-emitting area of each of the third sub-pixel and the fourth sub-pixel of the fourth pixel, and between the driving circuit and the light-emitting area of each of the first sub-pixel and the second sub-pixel of the fifth pixel.

In accordance with some embodiments of the display panel, the plurality of gate lines include a second gate line, wherein the second gate line is disposed between the driving circuit and the light-emitting area of each of the first sub-pixel and the second sub-pixel of the first pixel, between the driving circuit and the light-emitting area of each of the third sub-pixel and the fourth sub-pixel of the second pixel, between the driving circuit and the light-emitting area of each of the first sub-pixel and the second sub-pixel of the fourth pixel, and between the driving circuit and the light-emitting area of each of the third sub-pixel and the fourth sub-pixel of the fifth pixel.

In accordance with some embodiments of the display panel, the plurality of pixels include first to fifth pixels sequentially arranged in a second row and adjacent to each other, wherein the first and second rows are adjacent to each other in the column direction, wherein each of the first to fifth pixels of the second row includes first to fourth sub-pixels sequentially arranged in the row direction and adjacent to each other, wherein the plurality of gate lines include a third gate line, wherein the third gate line is disposed between the driving circuit and the light-emitting area of the third sub-pixel of the first pixel of the first row, between the driving circuit and the light-emitting area of the first sub-pixel of the second pixel of the first row, between the driving circuit and the light-emitting area of each of the second sub-pixel and the fourth sub-pixel of the third pixel of the first row, between the driving circuit and the light-emitting area of each of the first sub-pixel and the third sub-pixel of the third pixel of the second row, between the driving circuit and the light-emitting area of the fourth sub-pixel of the fourth pixel of the second row, and between the driving circuit and the light-emitting area of the second sub-pixel of the fifth pixel of the second row.

In accordance with some embodiments of the display panel, the plurality of gate lines include a fourth gate line, wherein the fourth gate line is disposed between the driving circuit and the light-emitting area of each of the first sub-pixel and the second sub-pixel of the first pixel of the second row, between the driving circuit and the light-emitting area of each of the third sub-pixel and the fourth sub-pixel of the second pixel of the second row, between the driving circuit and the light-emitting area of each of the first sub-pixel and the second sub-pixel of the fourth pixel of the second row, and between the driving circuit and the light-emitting area of each of the third sub-pixel and the fourth pixel of the fifth pixel of the second row.

In accordance with some embodiments of the display panel, the plurality of gate lines include a fifth gate line, wherein the fifth gate line is disposed between the driving circuit and the light-emitting area of each of the third sub-pixel and the fourth sub-pixel of the first pixel of the second row, between the driving circuit and the light-emitting area of each of the first sub-pixel and the second sub-pixel of the second pixel of the second row, between the driving circuit and the light-emitting area of each of the second sub-pixel and the fourth sub-pixel of the third pixel of the second row, between the driving circuit and the light-emitting area of the third sub-pixel of the fourth pixel of the second row, and between the driving circuit and the light-emitting area of the first sub-pixel of the fifth pixel of the second row.

In accordance with some embodiments of the display panel, the display panel further comprises: a high potential voltage line for applying a high potential voltage to each of the plurality of pixels, wherein the high potential voltage line extends in the column direction; and an additional high potential voltage line extending in the row direction, wherein one additional high potential voltage line is disposed every two rows.

In accordance with some embodiments of the display panel, the plurality of pixels comprise first and second pixels arranged in a first row and adjacent to each other, wherein each of the sub-pixels comprises a light-emitting area and a driving circuit, wherein in a plan view of the display panel, the driving circuit of each of the plurality of sub-pixels of each of the first and second pixels is disposed on one or the other of both opposing sides in a column direction of the light-emitting area of each of the plurality of sub-pixels of each of the first and second pixels.

In accordance with some embodiments of the display panel, the plurality of pixels comprise first pixel, second pixel, third pixel, fourth pixel and fifth pixel sequentially arranged in a second row and adjacent to each other, wherein the first and second rows are adjacent to each other in a column direction, wherein each of the first to fifth pixels of the second row comprises first to fourth sub-pixels sequentially arranged in the row direction and adjacent to each other, wherein the driving circuit of one of the plurality of sub-pixels of each of the first and second pixels of the second row is disposed on one of both opposing sides in a column direction of the light-emitting area of the one of the plurality of sub-pixels of each of the first and second pixels, and wherein each of the respective driving circuits of the others of the plurality of sub-pixels of each of the first and second pixels of the second row is disposed on the other of both opposing sides in the column direction of each of the respective light-emitting areas of the others of the plurality of sub-pixels of each of the first and second pixels.

In accordance with some embodiments of the display panel, the first pixel of the second row comprises: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the fourth sub-pixel is disposed on one of both opposing sides in the column direction of the light-emitting area of the fourth sub-pixel, and wherein each of the respective driving circuits of the first to third sub-pixels of the first pixel of the second row is disposed on the other of both opposing sides in the column direction of each of the respective light-emitting areas of the first to third sub-pixels.

In accordance with some embodiments of the display panel, the second pixel of the second row comprises: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the second sub-pixel is disposed on one of both opposing sides in the column direction of the light-emitting area of the second sub-pixel, and wherein each of the respective driving circuits of the first, third and fourth sub-pixels of the second pixel of the second row is disposed on the other of both opposing sides in the column direction of each of the respective light-emitting areas of the first, third and fourth sub-pixels.

In accordance with some embodiments of the display panel, the third pixel of the second row comprises: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein each of the respective driving circuits of the first to fourth sub-pixels of the third pixel of the second row is disposed on the same sides of both opposing sides in the column direction of the respective light-emitting areas of the first to fourth sub-pixels of the third pixel.

In accordance with some embodiments of the display panel, the fourth pixel of the second row comprises: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the third sub-pixel of the fourth pixel of the second row is disposed on one of both opposing sides in the column direction of the light-emitting area of the third sub-pixel, and wherein each of the respective driving circuits of the first, second and fourth sub-pixels of the fourth pixel of the second row is disposed on the other of both opposing sides in the column direction of each of the respective light-emitting areas of the first, second and fourth sub-pixels.

In accordance with some embodiments of the display panel, the fifth pixel of the second row comprises: a first sub-pixel; a second sub-pixel disposed at a position adjacent to the first sub-pixel; a third sub-pixel disposed at a position adjacent to the second sub-pixel; and a fourth sub-pixel disposed at a position adjacent to the third sub-pixel, wherein the driving circuit of the first sub-pixel of the fifth pixel of the second row is disposed on one of both opposing sides in the column direction of the light-emitting area of the first sub-pixel, and wherein each of the respective driving circuits of the second to fourth sub-pixels of the fifth pixel of the second row is disposed on the other of both opposing sides in the column direction of each of the respective light-emitting areas of the second to fourth sub-pixels.

Another aspect of the present disclosure provides a display device comprising: a display panel configured to drive five pixels arranged in the same row using two data lines; a data driver configured to supply a data voltage to the display panel via a plurality of data lines; and a gate driver configured to supply a gate signal to the display panel via a plurality of gate lines, wherein the display panel includes: a plurality of pixels, each pixel including a plurality of sub-pixels respectively emitting light of different colors; the plurality of data lines disposed to supply the data voltage to the plurality of pixels; and the plurality of gate lines disposed to supply the gate signal to the plurality of pixels.

In accordance with some embodiments of the display device, the sub-pixels included in each of the plurality of pixels are arranged so as to be sensed in a multiple manner based on the gate signal being applied the plurality of pixels via the gate line.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display panel configured to drive five pixels arranged in a same row using two data lines, wherein the display panel comprises:
a plurality of pixels, each pixel of the plurality of pixels including a plurality of sub-pixels respectively emitting light of different colors;
a plurality of data lines disposed to supply a data voltage to the plurality of pixels, wherein each of the plurality of data lines divides into a plurality of sub-data lines; and
a plurality of gate lines disposed to supply a gate signal to the plurality of pixels,
wherein the plurality of sub-pixels included in each pixel of the plurality of pixels are arranged so as to be sensed in a multiple manner based on the gate signal being applied to the plurality of pixels via a gate line of the plurality of gate lines.

2. The display panel of claim 1,
wherein each of the plurality of sub-data lines is constructed such that the data voltage is applied to three or two sub-pixels arranged in a first row via a first sub-data line of the plurality of sub-data lines, or the data voltage is applied to two or three sub-pixels arranged in a second row adjacent to the first row in a column direction via the first sub-data line.

3. The display panel of claim 1, wherein the plurality of pixels comprise a first pixel and a second pixel arranged in a first row and adjacent to each other,
wherein each of a plurality of sub-pixels of each of the first pixel and the second pixel comprises a light-emitting area and a driving circuit,
wherein in a plan view of the display panel, the driving circuit of a sub-pixel of the plurality of sub-pixels of each of the first pixel and the second pixel is disposed on a first side of opposing sides in a column direction of the light-emitting area of the sub-pixel, and
wherein each of respective driving circuits of sub-pixels of the plurality of sub-pixels other than the sub-pixel is disposed on a second side of opposing sides in a column direction of each of respective light-emitting areas of the sub-pixels other than the sub-pixel.

4. The display panel of claim 3, wherein the plurality of pixels further comprise a third pixel disposed in the first row and adjacent to the second pixel, and
wherein a respective driving circuit of each of a plurality of sub-pixels of the third pixel is respectively disposed on a same side of opposing sides in a column direction of a respective light-emitting area of each of the plurality of sub-pixels of the third pixel.

5. The display panel of claim 4, wherein the plurality of pixels further comprise a fourth pixel disposed in the first row and adjacent to the third pixel, and a fifth pixel disposed in the first row and adjacent to the fourth pixel,
wherein a driving circuit of a sub-pixel of a plurality of sub-pixels of each of the fourth pixel and the fifth pixel is disposed on a first side of opposing sides in a column direction of a light-emitting area of the sub-pixel, and
wherein each of respective driving circuits of sub-pixels of the plurality of sub-pixels other than the sub-pixel is disposed on a second side of opposing sides in a column direction of each of respective light-emitting areas of the sub-pixels other than the sub-pixel.

6. The display panel of claim 3, wherein the first pixel comprises:
a first sub-pixel;
a second sub-pixel disposed at a position adjacent to the first sub-pixel;
a third sub-pixel disposed at a position adjacent to the second sub-pixel; and
a fourth sub-pixel disposed at a position adjacent to the third sub-pixel,
wherein a driving circuit of the fourth sub-pixel is disposed on a first side of opposing sides in a column direction of a light-emitting area of the fourth sub-pixel, and
wherein each of respective driving circuits of the first sub-pixel, the second sub-pixel and the third sub-pixel is disposed on a second side of opposing sides in a column direction of each of respective light-emitting areas of the first sub-pixel, the second sub-pixel and the third sub-pixel.

7. The display panel of claim 3, wherein the second pixel comprises:
a first sub-pixel;
a second sub-pixel disposed at a position adjacent to the first sub-pixel;
a third sub-pixel disposed at a position adjacent to the second sub-pixel; and
a fourth sub-pixel disposed at a position adjacent to the third sub-pixel,
wherein a driving circuit of the second sub-pixel is disposed on a first side of opposing sides in a column direction of a light-emitting area of the second sub-pixel, and
wherein each of respective driving circuits of the first sub-pixel, the third sub-pixel and the fourth sub-pixel is disposed on a second side of opposing sides in a column direction of each of respective light-emitting areas of the first sub-pixel, the third sub-pixel and the fourth sub-pixel.

8. The display panel of claim 4, wherein the third pixel comprises:
a first sub-pixel;
a second sub-pixel disposed at a position adjacent to the first sub-pixel;
a third sub-pixel disposed at a position adjacent to the second sub-pixel; and
a fourth sub-pixel disposed at a position adjacent to the third sub-pixel,
wherein a driving circuit of the second sub-pixel is disposed on a first side of opposing sides in a column direction of a light-emitting area of the second sub-pixel, and
wherein each of respective driving circuits of the first sub-pixel, the second sub-pixel, the third sub-pixel and the fourth sub-pixel of the third pixel is disposed on a second side of opposing sides in a column direction of each of respective light-emitting areas of the first sub-pixel, the second sub-pixel, the third sub-pixel and the fourth sub-pixel of the third pixel.

9. The display panel of claim 5, wherein the fourth pixel comprises:
a first sub-pixel;
a second sub-pixel disposed at a position adjacent to the first sub-pixel;
a third sub-pixel disposed at a position adjacent to the second sub-pixel; and
a fourth sub-pixel disposed at a position adjacent to the third sub-pixel,
wherein a driving circuit of the third sub-pixel is disposed on a first side of opposing sides in a column direction of a light-emitting area of the third sub-pixel, and
wherein each of respective driving circuits of the first sub-pixel, the second sub-pixel and the fourth sub-pixel is disposed on a second side of opposing sides in a column direction of each of respective light-emitting areas of the first sub-pixel, the second sub-pixel and the fourth sub-pixel.

10. The display panel of claim 5, wherein the fifth pixel comprises:
a first sub-pixel;
a second sub-pixel disposed at a position adjacent to the first sub-pixel;
a third sub-pixel disposed at a position adjacent to the second sub-pixel; and
a fourth sub-pixel disposed at a position adjacent to the third sub-pixel,
wherein a driving circuit of the first sub-pixel is disposed on a first side of opposing sides in a column direction of a light-emitting area of the first sub-pixel, and
wherein each of respective driving circuits of the second sub-pixel, the third sub-pixel and the fourth sub-pixel is disposed on a second side of opposing sides in a column direction of each of respective light-emitting areas of the second sub-pixel, the third sub-pixel and the fourth sub-pixel.

11. The display panel of claim 3, wherein the plurality of pixels further comprise a third pixel disposed in the first row and adjacent to the second pixel, the third pixel comprising:
a first sub-pixel;
a second sub-pixel disposed at a position adjacent to the first sub-pixel;
a third sub-pixel disposed at a position adjacent to the second sub-pixel; and
a fourth sub-pixel disposed at a position adjacent to the third sub-pixel,
wherein a driving circuit of the fourth sub-pixel is disposed on a first side of opposing sides in a column direction of a light-emitting area of the fourth sub-pixel, and
wherein each of respective driving circuits of the first sub-pixel, the second sub-pixel and the third sub-pixel is disposed on a second side of opposing sides in a column direction of each of respective light-emitting areas of the first sub-pixel, the second sub-pixel and the third sub-pixel.

12. The display panel of claim 1, wherein each of the plurality of sub-pixels comprises a light-emitting area and a driving circuit,
wherein the plurality of pixels comprise a first pixel and a second pixel respectively disposed in a first row and a second row adjacent to each other in a column direction, wherein the first pixel and the second pixel are arranged in a same column,
wherein in a plan view of the display panel, the driving circuit of each of the plurality of sub-pixels of the first pixel is disposed on a first side of opposing sides in a column direction of the light-emitting area of each of the plurality of sub-pixels of the first pixel, and
wherein the driving circuit of each of the plurality of sub-pixels of the second pixel aligned with each of the plurality of sub-pixels of the first pixel in the column direction is disposed on a second side of opposing sides in a column direction of the light-emitting area of each of the plurality of sub-pixels of the second pixel aligned with each of the plurality of sub-pixels of the first pixel in the column direction.

13. The display panel of claim 12, wherein the plurality of sub-pixels arranged in each of the first pixel and the second pixel comprise a first group of four sub-pixels consecutively arranged in a row direction, and a second group of four sub-pixels consecutively arranged in the row direction, wherein the first group of four sub-pixels is adjacent to the second group of four sub-pixels in the row direction,
wherein the driving circuit of each sub-pixel of the first group of four sub-pixels is disposed on a first side of opposing sides in a column direction of the light-emitting area of each sub-pixel of the first group of four sub-pixels, and
wherein the driving circuit of each sub-pixel of the second group of four sub-pixels is disposed on a second side of opposing sides in a column direction of the light-emitting area of each sub-pixel of the second group of four sub-pixels.

14. The display panel of claim 3, wherein the plurality of pixels comprise the first pixel, the second pixel, a third pixel, a fourth pixel and a fifth pixel sequentially arranged in the first row and adjacent to each other,
wherein each of the first pixel, the second pixel, the third pixel, the fourth pixel and the fifth pixel of the first row comprises a first sub-pixel, a second sub-pixel, a third sub-pixel and a fourth sub-pixel sequentially arranged in a row direction and adjacent to each other,
wherein the plurality of gate lines comprise a first gate line, and
wherein the first gate line is disposed between a driving circuit and a light-emitting area of the fourth sub-pixel of the first pixel, between a driving circuit and a light-emitting area of the second sub-pixel of the second pixel, between a driving circuit and a light-emitting area of each of the first sub-pixel and the third sub-pixel of the third pixel, between a driving circuit and a light-emitting area of each of the third sub-pixel and the fourth sub-pixel of the fourth pixel, and between a driving circuit and a light-emitting area of each of the first sub-pixel and the second sub-pixel of the fifth pixel.

15. The display panel of claim 14, wherein the plurality of gate lines comprise a second gate line, and
wherein the second gate line is disposed between a driving circuit and a light-emitting area of each of the first sub-pixel and the second sub-pixel of the first pixel, between a driving circuit and a light-emitting area of each of the third sub-pixel and the fourth sub-pixel of the second pixel, between a driving circuit and a light-emitting area of each of the first sub-pixel and the second sub-pixel of the fourth pixel, and between a driving circuit and a light-emitting area of each of the third sub-pixel and the fourth sub-pixel of the fifth pixel.

16. The display panel of claim 14, wherein the plurality of pixels comprise a sixth pixel, a seventh pixel, an eighth pixel, a nineth pixel and a tenth pixel sequentially arranged in a second row and adjacent to each other, wherein the first row and the second row are adjacent to each other in the column direction,
wherein each of the sixth pixel, the seventh pixel, the eighth pixel, the nineth pixel and the tenth pixel comprises a first sub-pixel, a second sub-pixel, a third sub-pixel and the fourth sub-pixel sequentially arranged in the row direction and adjacent to each other,
wherein the plurality of gate lines comprise a third gate line, and
wherein the third gate line is disposed between a driving circuit and a light-emitting area of the third sub-pixel of the first pixel, between a driving circuit and a light-emitting area of the first sub-pixel of the second pixel, between a driving circuit and a light-emitting area of each of the second sub-pixel and the fourth sub-pixel of the third pixel, between a driving circuit and a light-emitting area of each of the first sub-pixel and the third sub-pixel of the eighth pixel, and between a driving circuit and a light-emitting area of the fourth sub-pixel of the nineth pixel.

17. The display panel of claim 16, wherein the plurality of gate lines comprise a fourth gate line, and
wherein the fourth gate line is disposed between a driving circuit and a light-emitting area of each of the first sub-pixel and the second sub-pixel of the sixth pixel, between a driving circuit and a light-emitting area of each of the third sub-pixel and the fourth sub-pixel of the seventh pixel, between a driving circuit and a light-emitting area of each of the first sub-pixel and the second sub-pixel of the nineth pixel, and between a driving circuit and a light-emitting area of each of the third sub-pixel and the fourth pixel of the tenth pixel.

18. The display panel of claim 16, wherein the plurality of gate lines comprise a fifth gate line, and
wherein the fifth gate line is disposed between a driving circuit and a light-emitting area of each of the third sub-pixel and the fourth sub-pixel of the sixth pixel, between a driving circuit and a light-emitting area of each of the first sub-pixel and the second sub-pixel of the seventh pixel, between a driving circuit and a light-emitting area of each of the second sub-pixel and the fourth sub-pixel of the eighth pixel, between a driving circuit and a light-emitting area of the third sub-pixel of the nineth pixel, and between a driving circuit and a light-emitting area of the first sub-pixel of the tenth pixel.

19. The display panel of claim 1, wherein the display panel further comprises:
a high potential voltage line disposed to apply a high potential voltage to each of the plurality of pixels, wherein the high potential voltage line is disposed in a column direction; and
an additional high potential voltage line disposed in a row direction intersecting the column direction,
wherein the additional high potential voltage line is disposed in every two rows of a plurality of rows of the display panel.

20. A display device, comprising:
a display panel configured to drive five pixels arranged in a same row using two data lines;
a data driver configured to supply a data voltage to the display panel via a plurality of data lines; and
a gate driver configured to supply a gate signal to the display panel via a plurality of gate lines,
wherein the display panel comprises:
a plurality of pixels, each pixel of the plurality of pixels including a plurality of sub-pixels respectively emitting light of different colors;
the plurality of data lines disposed to supply the data voltage to the plurality of pixels, wherein each of the plurality of data lines divides into a plurality of sub-data lines; and
the plurality of gate lines disposed to supply the gate signal to the plurality of pixels,
wherein the plurality of sub-pixels included in each of the plurality of pixels are arranged so as to be sensed in a multiple manner based on the gate signal being applied to the plurality of pixels via a gate line of the plurality of gate lines.
